(19) United States
(12) Patent Application Publication
(10) Pub. No.: US 2022/0301632 A1
(43) Pub. Date: Sep. 22, 2022

(54) SEMICONDUCTOR STORAGE DEVICE

(71) Applicant: KIOXIA CORPORATION, Tokyo (JP)

(72) Inventor: Takashi MAEDA, Kamakura Kanagawa (JP)

(21) Appl. No.: 17/459,328

(22) Filed: Aug. 27, 2021

(30) Foreign Application Priority Data
Mar. 19, 2021 (JP) 2021-045328

(51) Int. Cl. G11C 16/14; G11C 16/26; G11C 16/24; G11C 16/08; G11C 16/04; G11C 16/10; G11C 29/42

(52) U.S. Cl. CPC G11C 16/14; G11C 16/26; G11C 16/24; G11C 16/08; G11C 16/0433; G11C 16/102; G11C 29/42

(57) ABSTRACT

A semiconductor storage device includes a memory cell array including memory cell transistors connected in series between a bit line and a source line and word lines respectively connected to gates of the memory cell transistors. In the erasing operation to erase data stored in a selected memory cell transistor, while an erase voltage is applied to the bit line and the source line: a first voltage is applied to the word line connected to the gate of the selected memory cell transistor, a second voltage higher than the first voltage is applied to the word line connected to the gate of each memory cell transistor adjacent to the selected memory cell transistor, and a third voltage higher than the second voltage and lower than the erase voltage is applied to the word line connected to the gate of each memory cell transistor not adjacent to the selected memory cell transistor.

### CROSS-REFERENCE TO RELATED APPLICATION

This application is based upon and claims the benefit of priority from Japanese Patent Application No. 2021-045328, filed Mar. 19, 2021, the entire contents of which are incorporated herein by reference.

### FIELD

Embodiments described herein relate generally to a semiconductor storage device.

### BACKGROUND

A semiconductor storage device such as a NAND-type flash memory includes a plurality of memory cell transistors for storing data. Data can be individually written to or read from each of the memory cell transistors. However, it is common to erase data collectively from the plurality of memory cell transistors, for example, for each unit called a block.

Examples of related art include JP-A-2020-047644.

### BRIEF DESCRIPTION OF THE DRAWINGS

FIG. 1 is a block diagram illustrating a configuration example of a memory system according to a first embodiment.

FIG. 2 is a block diagram illustrating a configuration of a semiconductor storage device according to the first embodiment.

FIG. 3 is an equivalent circuit diagram illustrating a configuration of a memory cell array.

FIG. 4 is a cross-sectional view illustrating a configuration of the memory cell array.

FIG. 5 is a diagram illustrating an example of a threshold voltage distribution of a memory cell transistor.

FIG. 6 is a diagram illustrating voltages of various portions during an erasing operation of the first embodiment.

FIG. 7 is a timing diagram illustrating voltage changes in various portions during the erasing operation of the first embodiment.

FIG. 8 is a diagram illustrating voltages of various portions during the erasing operation according to a comparative example.

FIGS. 9A and 9B are diagrams illustrating changes of the threshold voltage distribution.

FIG. 10 is a diagram illustrating changes of threshold voltages.

FIG. 11 is a flowchart illustrating a flow of a process performed by a sequencer according to the first embodiment.

FIG. 12 is a flowchart illustrating a flow of a process performed by the sequencer according to a second embodiment.

FIGS. 13A to 13C are diagrams illustrating a concept of a process performed in a third embodiment.

FIG. 14 is a flowchart illustrating a flow of a process performed by the sequencer according to the third embodiment.

FIG. 15 is a diagram illustrating voltages of various portions during the erasing operation according to a fourth embodiment.

FIG. 16 is a timing diagram illustrating voltage changes in various portions during the erasing operation according to the fourth embodiment.

FIG. 17 is a diagram illustrating voltages of various portions during the erasing operation according to a fifth embodiment.

FIG. 18 is a diagram schematically illustrating a configuration of a memory cell array according to a sixth embodiment.

FIG. 19 is a diagram illustrating a configuration of a memory pillar according to the sixth embodiment.

### DETAILED DESCRIPTION

Embodiments provide a semiconductor storage device that can selectively erase data.

In general, according to one embodiment, the semiconductor storage device includes a memory cell array including a plurality of memory cell transistors that are connected to each other in series between a bit line and a source line and a plurality of word lines respectively connected to gates of the memory cell transistors, and a control circuit configured to control an operation of the memory cell array, including an erasing operation. In the erasing operation to erase data stored in a selected one of the memory cell transistors, an erase voltage is applied to the bit line and the source line, and while the erase voltage is applied to the bit line and the source line: a first voltage is applied to the word line connected to the gate of the selected memory cell transistor, a second voltage higher than the first voltage is applied to the word line connected to the gate of each of the memory cell transistors that are adjacent to the selected memory cell transistor, and a third voltage higher than the second voltage and lower than the erase voltage is applied to the word line connected to the gate of each of the memory cell transistors that are not adjacent to the selected memory cell transistor.

Hereinafter, embodiments of the present disclosure will be described with reference to the drawings. For better understanding of the description, the same components are denoted by the same reference numerals in each drawing, and duplicate description is omitted.

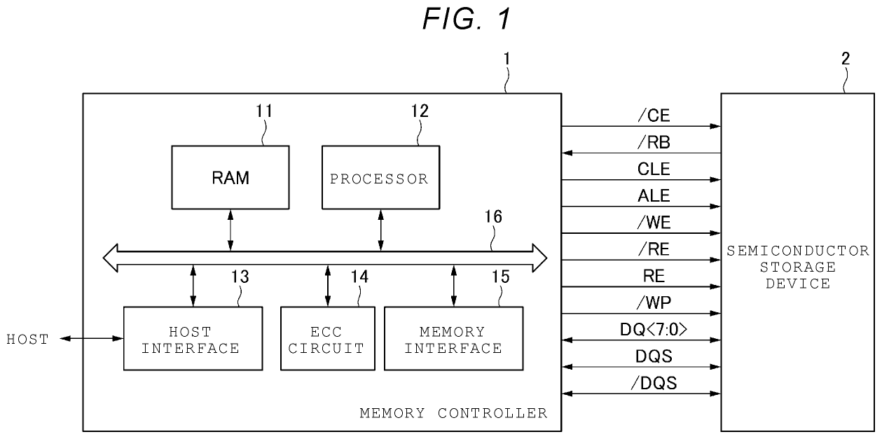

A first embodiment is described. A semiconductor storage device 2 according to the present embodiment is a nonvolatile storage device configured as a NAND-type flash memory. FIG. 1 illustrates a configuration example of a memory system including the semiconductor storage device 2, in a block diagram. This memory system includes a memory controller 1 and the semiconductor storage device 2. Further, the plurality of semiconductor storage devices 2 are provided in the memory system of FIG. 1, in practice. However, FIG. 1 illustrates only one semiconductor storage device. A specific configuration of the semiconductor storage device 2 is described below. This memory system can be connected to a host (not illustrated). The host is, for example, an electronic device such as a personal computer or a mobile terminal.

The memory controller 1 controls the writing of data to the semiconductor storage device 2 according to a write request from the host. In addition, the memory controller 1 controls the reading of data from the semiconductor storage device 2 according to a reading request from the host.

Signals including a chip enable signal /CE, a ready busy signal /RB, a command latch enable signal CLE, an address latch enable signal ALE, a write enable signal /WE, read enable signals /RE and RE, a write protect signal /WP, a data signal DQ<7:0>, and data strobe signals DQS and /DQS, are transmitted and received between the memory controller 1 and the semiconductor storage device 2.

The chip enable signal /CE is a signal that enables the semiconductor storage device 2. The ready busy signal /RB is a signal indicating whether the semiconductor storage device 2 is in a ready state or a busy state. The “ready state” is a state in which an instruction can be received from the outside. The “busy state” is a state in which an instruction cannot be received from the outside. The command latch enable signal CLE is a signal indicating that the signal DQ<7:0> is a command. The address latch enable signal ALE is a signal indicating that the signal DQ<7:0> is an address. The write enable signal /WE is a signal for capturing the received signal into the semiconductor storage device 2. In a single data rate (SDR) mode, at a rising edge of the signal /WE, it is instructed to capture the signal DQ<7:0> as a command, an address, and data transmitted to the semiconductor storage device 2. In a double data rate (DDR) mode, at the rising edge of the signal /WE, it is instructed to capture the signal DQ<7:0> as a command or an address transmitted to the nonvolatile memory 2. The signal is asserted whenever a command, an address, and data are received by the memory controller 1.

The read enable signal /RE is a signal for causing the memory controller 1 to read data from the semiconductor storage device 2. The signal RE is a complementary signal of the signal /RE. These are used for controlling an operation timing of the semiconductor storage device 2, for example, when the signal DQ<7:0> is output. More specifically, in the single data rate mode, at a falling edge of the signal /RE, it is instructed to output the signal DQ<7:0> as data to the nonvolatile memory 2. In the double data rate mode, at the falling edge and the rising edge of the signal /RE, it is instructed to output the signal DQ<7:0> as data to the nonvolatile memory 2. The write protect signal /WP is a signal for instructing the semiconductor storage device 2 to prohibit writing and erasing of data. The signal DQ<7:0> is transmitted and received between the semiconductor storage device 2 and the memory controller 1 and includes a command, an address, and data. The data strobe signal DQS is a signal for controlling a timing of inputting and outputting the signal DQ<7:0>. The signal /DQS is a complementary signal of the signal DQS. More specifically, in the double data rate mode, at the falling edge and the rising edge of the signal DQS, it is instructed to take the signal DQ<7:0> as data in the nonvolatile memory 2. In the double data rate mode, the signal DQS is generated in the falling edge and the rising edge of the signal /RE and output from the nonvolatile memory 2 together with the signal DQ<7:0> as data.

The memory controller 1 includes a RAM 11, a processor 12, a host interface 13, an ECC circuit 14, and a memory interface 15. The RAM 11, the processor 12, the host interface 13, the ECC circuit 14, and the memory interface 15 are connected to each other via an internal bus 16.

The host interface 13 outputs a request, user data (e.g., write data), and the like received from the host to the internal bus 16. The host interface 13 transmits user data read from the semiconductor storage device 2, a response from the processor 12, and the like to the host.

The memory interface 15 controls a process of writing user data and the like to the semiconductor storage device 2 and a process of reading the user data and the like from the semiconductor storage device 2 based on the instruction of the processor 12.

The processor 12 controls the memory controller 1. The processor 12 is, for example, a CPU or an MPU. When receiving a request from the host via the host interface 13, the processor 12 performs control according to the request. For example, the processor 12 instructs the memory interface 15 to write user data and a parity to the semiconductor storage device 2 according to the request from the host. The processor 12 instructs the memory interface 15 to read the user data and the parity from the semiconductor storage device 2 according to the request from the host.

The processor 12 determines a storage region (also referred to as a memory region) in the semiconductor storage device 2 with respect to the user data accumulated in the RAM 11. The user data is stored in the RAM 11 via the internal bus 16. The processor 12 determines the memory region for a page of data (page data), where one page of data is a unit writing. Hereinafter, the user data stored in one page of the semiconductor storage device 2 is referred to as “unit data”. The unit data is generally encoded and stored in the semiconductor storage device 2 as a code word. In the present embodiment, the encoding is optional. The memory controller 1 may store the unit data in the semiconductor storage device without encoding. However, FIG. 1 illustrates a configuration of encoding data as a configuration example. When the memory controller 1 does not encode data, the page data is identical to the unit data. In addition, one code word may be generated based on one item of unit data, and one code word may be generated based on divided data obtained by dividing the unit data. Also, one code word may be generated by using a plurality of items of unit data.

The processor 12 determines a memory region of the semiconductor storage device 2 as a writing destination for each unit data. A physical address is assigned to the memory region of the semiconductor storage device 2. The processor 12 manages a memory region as a writing destination of the unit data by using the physical address. The processor 12 instructs the memory interface 15 to designate the determined memory region (e.g., in the form of a physical address) and write the user data to the semiconductor storage device 2. The processor 12 manages the correspondence between the logical address (in particular, the logical address managed by the host) and the physical address of the user data. When receiving the reading request including the logical address from the host, the processor 12 determines the physical address corresponding to the logical address, designates the physical address, and instructs the memory interface 15 to read the user data.

The ECC circuit 14 encodes the user data stored in the RAM 11 and generates the code word. The ECC circuit 14 decodes the code word read from the semiconductor storage device 2. The ECC circuit 14 detects an error in the data and corrects the error, for example, by using a checksum placed in the user data.

The RAM 11 temporarily stores the user data received from the host until storing the user data in the semiconductor storage device 2 or temporarily stores the data read from the semiconductor storage device 2 until the data is transmitted to the host. The RAM 11 is, for example, a general-purpose memory such as an SRAM or a DRAM.

FIG. 1 illustrates a configuration example in which the memory controller 1 includes the ECC circuit 14 and the memory interface 15, separately. However, the ECC circuit 14 may be incorporated in the memory interface 15. In addition, the ECC circuit 14 may be incorporated in the semiconductor storage device 2. Specific configurations or arrangement of elements illustrated in FIG. 1 are not particularly limited those illustrated.

When the write request is received from the host, the memory system of FIG. 1 operates as follows. The processor 12 temporarily stores data to be written in the RAM 11. The processor 12 reads the data stored in the RAM 11 and inputs the data to the ECC circuit 14. The ECC circuit 14 encodes the input data and inputs the code word to the memory interface 15. The memory interface 15 writes the code word to the semiconductor storage device 2.

When the read request is received from the host, the memory system of FIG. 1 operates as follows. The memory interface 15 inputs the code word read from the semiconductor storage device 2 to the ECC circuit 14. The ECC circuit 14 decodes the code word and stores the decoded data in the RAM 11. The processor 12 transmits the data stored in the RAM 11 to the host via the host interface 13.

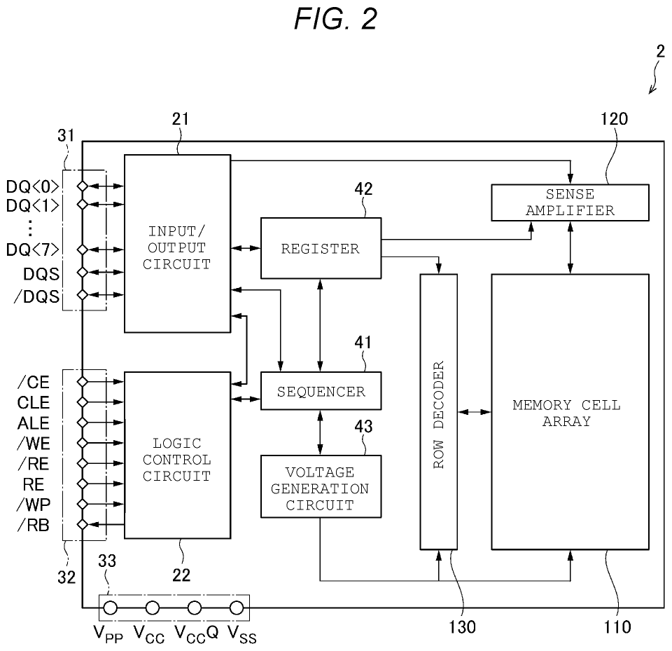

The configuration of the semiconductor storage device 2 is described. As illustrated in FIG. 2, the semiconductor storage device 2 includes a memory cell array 110, a sense amplifier 120, a row decoder 130, an input/output circuit 21, a logic control circuit 22, a sequencer 41, a register 42, a voltage generation circuit 43, an input/output pad group 31, a logic control pad group 32, and a power supply input terminal group 33.

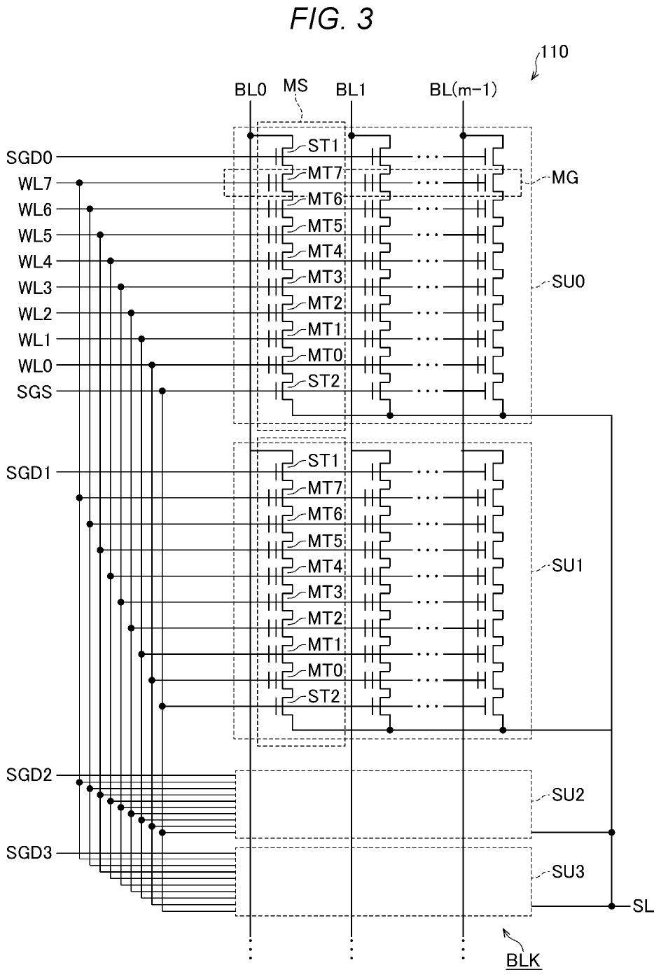

The memory cell array 110 is a portion that stores data. FIG. 3 illustrates a configuration of the memory cell array 110 as an equivalent circuit diagram. The memory cell array 110 is configured with a plurality of blocks BLK, but FIG. 3 illustrates only one block BLK. The configurations of the other blocks BLK in the memory cell array 110 are the same as the configuration illustrated in FIG. 3.

As illustrated in FIG. 3, the block BLK includes, for example, four string units SU (SU0 to SU3). Each of the string units SU includes a plurality of memory strings MS. Each of the memory strings MS includes eight memory cell transistors MT (MT0 to MT7) and select transistors ST1 and ST2, and has a configuration in which these are connected to each other in series.

The number of memory cell transistors MT is not limited to 8, and may be, for example, 32, 48, 64, or 96. For example, in order to improve the cutoff characteristic, the select transistors ST1 and ST2 each may be configured with a plurality of transistors, not with a single transistor. Further, a dummy cell transistor may be provided between the memory cell transistors MT and the select transistors ST1 and ST2.

The memory cell transistors MT in each of the memory strings MS are provided between the select transistors ST1 and the select transistors ST2, and are connected to each other in series. The memory cell transistor MT7 on one end side are connected to sources of the select transistors ST1, and the memory cell transistors MT0 on the other end side are connected to drains of the select transistors ST2.

Gates of the select transistors ST1 of each of the string units SU0 to SU3 are commonly connected to select gate lines SGD0 to SGD3, respectively. The gates of the select transistors ST2 are commonly connected to the same select gate line SGS across the plurality of string units SU in the same block BLK.

In the memory cell array 110, a plurality of word lines WL (WL0 to WL7) individually connected to gates of the memory cell transistors MT0 to MT7 are provided. The gates of the memory cell transistors MT0 to MT7 in the same block BLK are commonly connected to the word lines WL0 to WL7, respectively. That is, the word lines WL0 to WL7 and the select gate line SGS are commonly used across the plurality of string units SU0 to SU3 in the same block BLK, but the select gate lines SGD are individually provided for each of the string units SU0 to SU3 even in the same block BLK.

The memory cell array 110 is provided with m bit lines BL (BL0, BL1, . . . , and BL(m−1)). The “m” is an integer indicating the number of the memory strings MS in one string unit SU. With respect to the memory strings MS, the drains of the select transistors ST1 are connected to the corresponding bit lines BL. The sources of the select transistors ST2 are connected to a source line SL. The source line SL is commonly connected to the sources of the plurality of select transistors ST2 in the block BLK.

Data is collectively read and written with respect to the plurality of memory cell transistors MT that are connected to one word line WL and belong to one string unit SU.

According to the present embodiment, in the erasing operation, data stored in the plurality of memory cell transistors MT in the same block BLK is not collectively erased. Instead, only a portion of data is selectively erased. Specifically, while data stored in all of the memory cell transistors MT connected the specific word line WL is erased, data stored in the other memory cell transistors MT can be retained.

The memory cell transistors MT each can store 3-bit data including an upper bit, a middle bit, and a lower bit. That is, the semiconductor storage device 2 according to the present embodiment employs a TLC method of storing 3-bit data in one memory cell transistor MT as a method of writing data to the memory cell transistor MT. Instead, as the method of writing data to the memory cell transistor MT, an MLC method of storing 2-bit data in one memory cell transistor MT, an SLC method of storing 1-bit data in one memory cell transistor MT or the like may be employed.

In the following description, a set of 1-bit data stored in the plurality of memory cell transistors MT that are connected to one word line WL and belong to one string unit SU is referred to as a “page”. In FIG. 3, the set of memory cell transistors MT described above is denoted by a reference numeral “MG”.

According to the present embodiment, when 3-bit data is stored in one memory cell transistor MT, the set of memory cell transistors MT connected to the common word line WL in one string unit SU can store data of three pages.

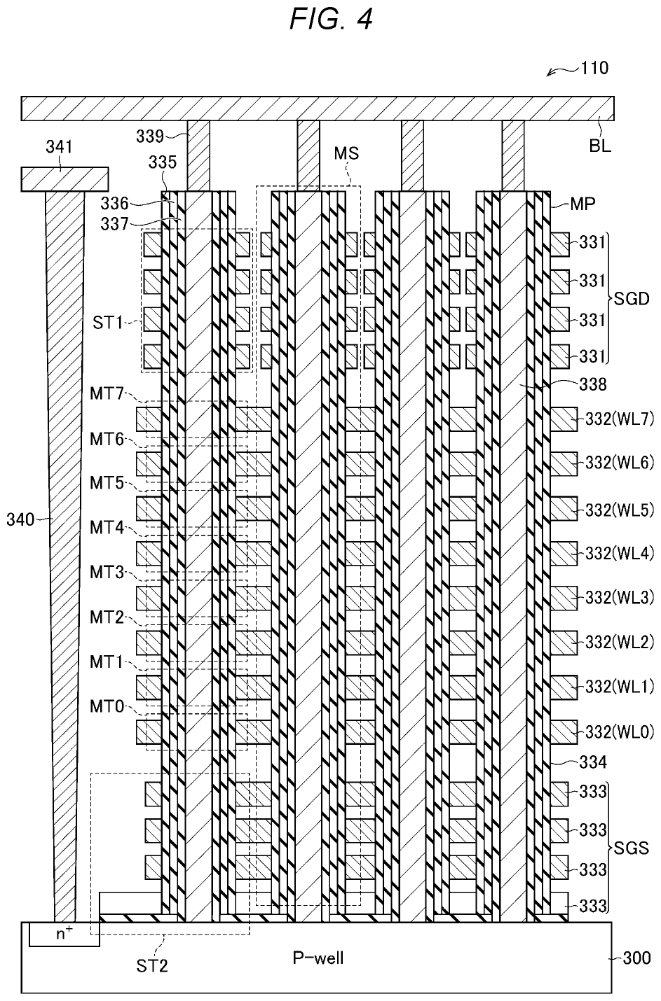

FIG. 4 illustrates a configuration of the memory cell array 110 as a schematic cross-sectional view. As illustrated in FIG. 4, in the memory cell array 110, the plurality of memory strings MS are formed on a p-type well region (P-well) of a semiconductor substrate 300.

A plurality of wiring layers 333 functioning as the select gate line SGS, a plurality of wiring layers 332 functioning as the word lines WL, and a plurality of wiring layers 331 functioning as the select gate lines SGD are stacked on the p-type well region. Insulating layers (not illustrated) are arranged between the stacked wiring layers 333, 332, and 331.

A plurality of memory holes 334 are formed in the memory cell array 110. The memory holes 334 are holes that are formed to penetrate the wiring layers 333, 332, and 331, and the insulating layers provided therebetween in the vertical direction and to reach the p-type well region. A block insulating film 335, a charge storage layer 336, and a gate insulating film 337 are sequentially formed on the side surface of the memory hole 334, and a semiconductor pillar 338 is further embedded inside thereof. The semiconductor pillar 338 is, for example, made of polysilicon, and functions as a region in which a channel is formed during the operations of the memory cell transistors MT and the select transistors ST1 and ST2 in the memory string MS. In this manner, a columnar body including the block insulating film 335, the charge storage layer 336, the gate insulating film 337, and the semiconductor pillars 338 is formed inside the memory holes 334. This columnar body is referred to as a “memory pillar MP”.

In the memory pillar MP formed inside the memory hole 334, portions intersecting respectively with the stacked wiring layers 333, 332, and 331 function as transistors. Among these plurality of transistors, those in portions intersecting with the wiring layers 331 function as the select transistor ST1. Among the plurality of transistors, those in portions intersecting with the wiring layers 332 function as the memory cell transistors MT (MT0 to MT7). Among the plurality of transistors, those in portions intersecting with the wiring layers 333 function as the select transistors ST2. In this configuration, the memory pillars MP formed inside the memory holes 334 function as the memory strings MS described with reference to FIG. 3. The semiconductor pillars 338 inside the memory pillars MP are portions that function as channels of the memory cell transistors MT or the select transistors ST1 and ST2.

A wiring layer that functions as the bit line BL is formed on the semiconductor pillars 338. Contact plugs 339 that connect the semiconductor pillars 338 and the bit lines BL to each other are formed at the upper ends of the semiconductor pillars 338.

In the front surface of the p-type well region, n+-type impurity diffusion layers and p+-type impurity diffusion layers (not illustrated) are formed. A contact plug 340 is formed on the n+-type impurity diffusion layer, and a wiring layer 341 is formed on the contact plug 340. The wiring layer 341 is a wiring for adjusting a voltage of the source line SL and is connected to the memory strings MS through an inversion layer formed in the p-type well region directly below the select gate line SGS during reading. The p+-type impurity diffusion layer is a wiring for adjusting a voltage of the p-type well region.

A plurality of configurations that are the same as the configuration illustrated in FIG. 4 is arranged along the depth direction of the paper surface of FIG. 4. One string unit SU is formed by the set including the plurality of memory strings MS arranged in a plane that extends in the depth direction of the paper surface of FIG. 4.

In the present embodiment, as described above, the p-type well region of the semiconductor substrate 300 is used as the source line SL. Instead, a conductive layer formed at the position on the upper side of the semiconductor substrate 300 may be used as the source line SL. With such an arrangement, a peripheral circuit such as the sense amplifier 120 may be arranged in the portion between the semiconductor substrate 300 and the conductive layer.

The description is continued referring back to FIG. 2. The sense amplifier 120 is a circuit for adjusting a voltage applied to the bit lines BL, reading the cell current flowing through the bit lines BL, and converting the cell current into data. The sense amplifier 120 obtains read data that is read from the memory cell transistors MT to the bit lines BL during the reading of data and transfers the obtained read data to the input/output circuit 21. The sense amplifier 120 transfers the write data that is written via the bit lines BL to the memory cell transistors MT during the writing of data. The operation of the sense amplifier 120 is controlled by the sequencer 41 described below.

The row decoder 130 is a circuit that is configured as a switch group (not illustrated) in order to apply the voltage to the word lines WL. The row decoder 130 receives a block address and a row address from the register 42, selects the corresponding block BLK based on the block address, and also selects the corresponding word line WL based on the row address. The row decoder 130 switches the opening and closing of switches in the switch group so that the voltage from the voltage generation circuit 43 is applied to the selected word line WL. The operation of the row decoder 130 is controlled by the sequencer 41.

The input/output circuit 21 transmits and receives the signal DQ<7:0> and the data strobe signals DQS and /DQS to and from the memory controller 1. The input/output circuit 21 transfers the command and the address in the signal DQ<7:0> to the register 42. The input/output circuit 21 transmits and receives the write data and the read data to and from the sense amplifier 120.

The logic control circuit 22 receives the chip enable signal /CE, the command latch enable signal CLE, the address latch enable signal ALE, the write enable signal /WE, the read enable signals /RE and RE, and the write protect signal /WP from the memory controller 1. The logic control circuit 22 transfers the ready busy signal /RB to the memory controller 1 and notifies the outside of the state of the semiconductor storage device 2.

The sequencer 41 controls operations of each unit including the memory cell array 110 based on control signals input from the memory controller 1 to the input/output circuit or the logic control circuit 22. The sequencer 41 corresponds to a “control circuit” according to the present embodiment. Both of the sequencer 41 and the logic control circuit 22 can be regarded as “control circuits” in the present embodiment.

The register 42 is a portion that temporarily stores the command or the address. A command that instructs the write operation or the read operation, the erasing operation, and the like is stored in the register 42. The command is input from the memory controller 1 to the input/output circuit 21, then transferred from the input/output circuit 21 in the register 42, and stored.

The register 42 also stores the address corresponding to the command. The address is input from the memory controller to the input/output circuit 21, transferred from the input/output circuit 21 to the register 42, and stored.

Further, the register 42 stores status information indicating an operation state of the semiconductor storage device 2. The status information is updated by the sequencer 41 according to the operation state of the memory cell array 110 or the like. The status information is output from the input/output circuit 21 to the memory controller 1 as the state signal according to the request from the memory controller 1.

The voltage generation circuit 43 is a portion where voltages respectively required for the write operation, the read operation, and the erasing operation of data in the memory cell array 110 are generated. Examples of the voltage include voltages applied to the word lines WL respectively and voltages applied to the bit lines BL, respectively. The operation of the voltage generation circuit 43 is controlled by the sequencer 41.

The input/output pad group 31 is a portion where a plurality of terminals (also referred to as pads) are provided, in order to transmit and receive signals between the memory controller 1 and the input/output circuit 21. The terminals are individually provided to correspond to the signal DQ<7:0>, and the data strobe signals DQS and /DQS, respectively.

The logic control pad group 32 is a portion where a plurality of terminals (also referred to as pads) are provided, in order to transmit and receive signals between the memory controller 1 and the logic control circuit 22. The terminals are individually provided to correspond to the chip enable signal /CE, the command latch enable signal CLE, the address latch enable signal ALE, the write enable signal /WE, the read enable signals /RE and RE, the write protect signal /WP, and the ready busy signal /RB, respectively.

The power supply input terminal group 33 is a portion where a plurality of terminals are provided in order to receive the application of voltages required for the operation of the semiconductor storage device 2. Power supply voltages Vcc, VccQ, and Vpp, and a ground voltage Vss are included in the voltages applied to the terminals, respectively.

The power supply voltage Vcc is a circuit power supply voltage applied from the outside as the operation power supply, and for example, the voltage of about 3.3 V. The power supply voltage VccQ is, for example, the voltage of 1.2 V. The power supply voltage VccQ is the voltage used when the signals are transmitted and received between the memory controller 1 and the semiconductor storage device 2. The power supply voltage Vpp is a power supply voltage higher than the power supply voltage Vcc, and is, for example, the voltage of 12 V.

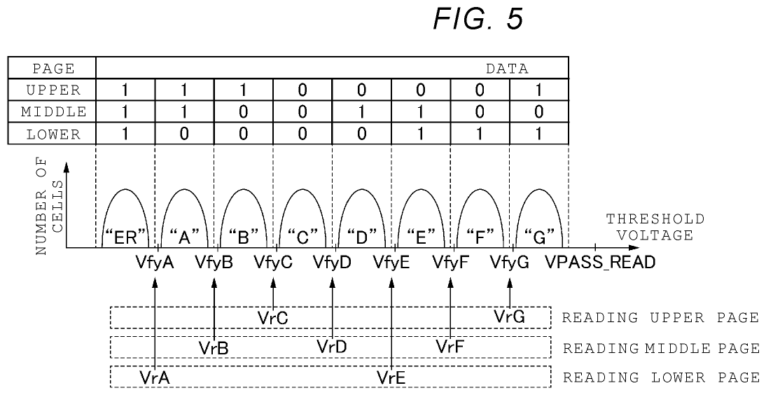

FIG. 5 is a diagram schematically illustrating the threshold voltage distribution of the memory cell transistors MT or the like. The diagram in the middle of FIG. 5 illustrates the correspondence relationship between the threshold voltages of the memory cell transistors MT (horizontal axis) and the numbers of the memory cell transistors MT (vertical axis).

When the TLC method is employed as in the present embodiment, the plurality of memory cell transistors MT form eight threshold voltage distributions as illustrated in the middle of FIG. 5. These eight threshold voltage distributions are referred to as an “ER” state, an “A” state, a “B” state, a “C” state, a “D” state, an “E” state, an “F” state, and a “G” state in an order from the lower threshold voltage side.

Columns of the table on the upper side of FIG. 5 correspond to states of the threshold voltages, respectively, and indicate examples of data assigned to the different states. As shown in the table, for example, different items of three-bit data as below can be assigned to the “ER” state, the “A” state, the “B” state, the “C” state, the “D” state, the “E” state, the “F” state, and the “G” state, respectively.

“ER” state: “111” (“lower bit/middle bit/upper bit”)

“A” state: “011”

“B” state: “001”

“C” state: “000”

“D” state: “010”

“E” state: “110”

“F” state: “100”

“G” state: “101”

Verification voltages respectively used for the write operations are set between a pair of adjacent threshold voltage distributions. Specifically, verification voltages VfyA, VfyB, VfyC, VfyD, VfyE, VfyF, and VfyG respectively corresponding to the “A” state, the “B” state, the “C” state, the “D” state, the “E” state, the “F” state, and the “G” state are set.

The verification voltage VfyA is set between the maximum threshold voltage in the “ER” state and the minimum threshold voltage in the “A” state. If the verification voltage VfyA is applied to the memory cell transistors MT, the memory cell transistor MT with the threshold voltage in the “ER” state transitions to the ON state, and the memory cell transistor MT with the threshold voltage in the threshold voltage distribution of the “A” state or higher transitions to the OFF state.

The other verification voltages VfyB, VfyC, VfyD, VfyE, VfyF, and VfyG are set in the same manner as the verification voltage VfyA. The verification voltage VfyB is set between the “A” state and the “B” state, the verification voltage VfyC is set between the “B” state and the “C” state, the verification voltage VfyD is set between the “C” state and the “D” state, the verification voltage VfyE is set between the “D” state and the “E” state, the verification voltage VfyF is set between the “E” state and the “F” state, and the verification voltage VfyG is set between the “F” state and the “G” state.

For example, the verification voltage VfyA may be set to 0.8 V, the verification voltage VfyB may be set to 1.6 V, the verification voltage VfyC may be set to 2.4 V, the verification voltage VfyD may be set to 3.1 V, the verification voltage VfyE may be set to 3.8 V, the verification voltage VfyF may be set to 4.6 V, the verification voltage VfyG may be set to 5.6V, respectively. However, the embodiment is not limited thereto, and the verification voltages VfyA, VfyB, VfyC, VfyD, VfyE, VfyF, and VfyG may be appropriately set stepwise in the range of 0 V to 7.0 V.

Read voltages used for read operations are set between the adjacent threshold voltage distributions, respectively. The “read voltage” is a voltage applied to the word line WL connected to the memory cell transistor MT to be read during the read operation. In the read operation, the data is determined based on the determination result whether the threshold voltage of the memory cell transistor MT to be read is higher than the applied read voltage.

As schematically illustrated on the lower side of FIG. 5, specifically, a read voltage VrA that determines whether the threshold voltage of the memory cell transistor MT is in the “ER” state or in the “A” state or higher is set between the maximum threshold voltage in the “ER” state and the minimum threshold voltage in the “A” state.

The other read voltages VrB, VrC, VrD, VrE, VrF, and VrG are also set in the same manner as the read voltage VrA. The read voltage VrB is set between the “A” state and the “B” state, the read voltage VrC is set between the “B” state and the “C” state, the read voltage VrD is set between the “C” state and the “D” state, the read voltage VrE is set between the “D” state and the “E” state, the read voltage VrF is set between the “E” state and the “F” state, and the read voltage VrG is set between the “F” state and the “G” state.

Also, a read pass voltage VPASS_READ is set to the voltage higher than the maximum threshold voltage of the highest threshold voltage distribution (for example, the “G” state). The memory cell transistor MT in which the read pass voltage VPASS_READ is applied to the gate transitions to the ON state regardless of the stored data.

Further, the verification voltages VfyA, VfyB, VfyC, VfyD, VfyE, VfyF, and VfyG are set to voltages, for example, higher than the read voltages VrA, VrB, VrC, VrD, VrE, VrF, and VrG, respectively. That is, the verification voltages VfyA, VfyB, VfyC, VfyD, VfyE, VfyF, and VfyG are set to be in near the lower portions of the threshold voltage distributions of the “A” state, the “B” state, the “C” state, the “D” state, the “E” state, the “F” state, and the “G” state, respectively.

When the data assignment as described above is applied, the one-page data of the lower bit (lower page data) in the read operation can be confirmed by the read result using the read voltages VrA and VrE. The one-page data of the middle bit (middle page data) can be confirmed by the read result using the read voltages VrB, VrD, and VrF. The one-page data of the upper bit (upper page data) can be confirmed by the read result using the read voltages VrC and VrG.

The assignment of the data described above is merely an example, and the actual assignment of data is not limited to this. The data of two bits or four bits or more may be stored in one memory cell transistor MT. In addition, the number of threshold voltage distributions in which data can be assigned may be 7 or less and may be 9 or more.

In the write operation of writing data in the memory cell transistor MT, the program operation and the verification operation are performed. The “program operation” is an operation of injecting electrons to the charge storage layers 336 of a portion of the memory cell transistors MT to change the threshold voltages of the memory cell transistors MT. The “verification operation” is an operation of reading the data after the program operation to verify whether the threshold voltage of the memory cell transistor MT reaches the target state. The memory cell transistor MT of which the threshold voltage reaches the target state is then write-inhibited.

In the program operation, in the memory cell transistor MT to be written, the voltage of the channel is set to, for example, 0 V, and the voltage of the word line connected to the gate is set to, for example, 20 V. In this manner, if the voltage is applied so that the gate has a higher voltage, electrons are injected to the charge storage layer 336 of the memory cell transistor MT, and the threshold voltage of the memory cell transistor MT rises. In the program operation, the voltage applied to the word line is not limited to 20 V, and a different voltage may be applied as long as the threshold voltage can be raised by injecting electrons to the charge storage layer 336 of the memory cell transistor MT. Further, as a specific aspect of the program operation, various well-known methods can be used, and thus specific descriptions thereof is omitted.

In the verification operation and the read operation, a predetermined read voltage (VrA or the like) or a predetermined verification voltage (VfyA or the like) is applied to the gate of the memory cell transistor MT to be read. A read pass voltage VPASS_READ is applied to the gates of the other memory cell transistors MT that belong to the same memory string MS as the corresponding memory cell transistor MT. In this state, the threshold voltage of the memory cell transistor MT is determined based on the size of the current that flows between the memory string MS and the bit line. Further, as specific aspects of the verification operation and the read operation, various well-known methods can be used, and thus the specific description thereof is omitted.

The erasing operation performed by the semiconductor storage device 2 according to the present embodiment is described. As described above, in the erasing operation of the present embodiment, the selective erasure is performed so that, while data stored in all of the memory cell transistors MT connected the specific word line WL is erased, data stored in the other memory cell transistors MT is retained. That is, data on the entire layer connected to the specific word line WL is erased. That is, the erasing operation of the present embodiment can be referred to as “layer erasure”. Further, embodiments may be applied to a plurality of word lines WL. Thus, “the specific word line WL” may be one word line WL or may be the plurality of word lines WL.

Among the plurality of memory cell transistors MT in the block BLK, in the erasing operation of erasing data stored in a portion of the memory cell transistors MT as above, the memory cell transistor MT that is an erasing target is hereinafter also referred to as a “selected memory cell transistor”. In addition, the pair of memory cell transistors MT that belong to the same memory string MS as the selected memory cell transistor and arranged at positions adjacent to the selected memory cell transistor are hereinafter also referred to as “adjacent memory cell transistors”. Further, the other memory cell transistors MT that belong to the same memory string MS as the selected memory cell transistor and the adjacent memory cell transistors are hereinafter also referred to as “non-selected memory cell transistor”.

In the present embodiment, the layer erasure as above is performed. Therefore, the sequencer 41, which is the control circuit, performs the erasing operation on all of the selected memory cell transistors MT connected to the specific word line WL.

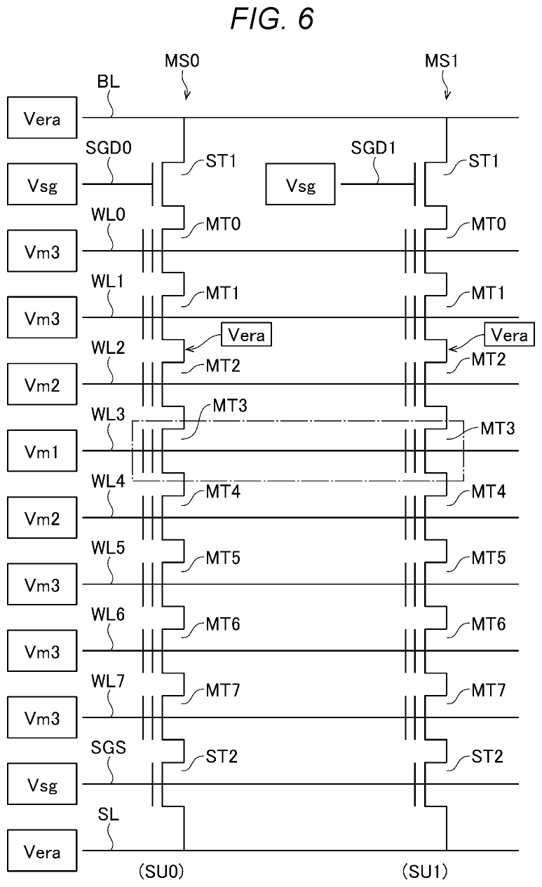

The equivalent circuit diagram of FIG. 6 illustrates the pair of the memory strings MS (MS0 and MS1) connected to the same bit line BL. The memory string MS0 belongs to the string unit SU0, and the memory string MS1 belongs to the string unit SU1. Hereinafter, voltages of various elements of the memory strings during the erasing operation are described with reference to FIG. 6.

In the example of FIG. 6, all of the memory cell transistors MT connected to the word line WL3 are set as an erasure target. In FIG. 6, the memory cell transistors MT that are erasure targets, are surrounded by an alternate long and short dash line. The memory cell transistors MT that are erasure targets also include memory cell transistors that belong to the string units SU2 and SU3 (not illustrated) and other memory cell transistors MT3 arranged in the depth direction of the paper surface in FIG. 6.

In the example of FIG. 6, the memory cell transistors MT3 of each memory string MS correspond to the “selected memory cell transistor” described above. Memory cell transistors MT2 and memory cell transistors MT4 of each memory string MS correspond to the “adjacent memory cell transistors” described above. The other memory cell transistors MT0 to MT1, and MT5 to MT7 correspond to the “non-selected memory cell transistors” described above.

Character strings such as “Vera” or “Vsg” surrounded by rectangular frames in FIG. 6 indicate voltages of the corresponding element. When the erasing operation is performed, the process of adjusting the voltages of each element as in FIG. 6 is implemented by operations of the sense amplifier 120, the row decoder 130, the voltage generation circuit 43, and the like based on the control by the sequencer 41.

As illustrated in FIG. 6, when the layer erasure is performed, the voltages of the bit line BL and the source line SL are set to Vera. “Vera” is the voltage required to erase data in the memory cell transistor MT, and for example, 20 V.

The voltages of the select gate lines SGD0, SGD1, and SGD are set to Vsg. “Vsg” is a voltage lower than Vera, and is, for example, 13 V. In the select transistors ST1 and ST2, GIDL is generated based on the voltage difference between Vera and Vsg, and channels of the memory strings MS are charged with the generated holes. As a result, in the memory strings MS0 and MS1, the voltages of the channels rise to Vera.

In the erasing operation, the voltage applied to the bit line BL and the source line SL is not limited to 20 V, and the voltage applied to the select gate lines SGD0, SGD1, and SGD is not limited to 13 V. As long as holes can be generated by GIDL in the select transistors ST1 and ST2, voltages different from the above voltages may be applied to the bit line BL, the source line SL, and the select gate lines SGD0, SGD1, and SGD. In this manner, the numerical values of the voltages of each element according to the present embodiment are merely examples, and the specific numerical values are not limited to numerical values described in the present embodiment.

Further in the present embodiment, the p-type well region of the semiconductor substrate 300 is used as the source line SL, and thus the generation of GIDL in the select transistors ST2 is not essential. In the select transistors ST2, by setting the voltages as described above, the holes that are present in the p-type well region easily pass. Accordingly, the voltage rise of the channels described above is promoted. The generation of GIDL in the select transistors ST2 occurs in addition to the above-described phenomenon.

The voltages of the channels in the memory strings MS0 and MS1 and the like are set to Vera as described above, and the voltage of the word line WL (WL3) connected to the gates of the selected memory cell transistors (MT3) is set to Vm1. “Vm1” is, for example, the ground voltage (0 V).

The voltages of the word lines WL (WL2 and WL4) connected to the gates of the adjacent memory cell transistors (MT2 and MT4) are set to Vm2. “Vm2” is a voltage higher than Vm1 and is, for example, 10 V.

Further, the voltages of the word lines WL (WL0 to WL1, and WL5 to WL7) connected to the gates of the non-selected memory cell transistors (MT0 to MT1, and MT5 to MT7) are set to Vm3. “Vm3” is a voltage higher than Vm2 and is, for example, 16 V.

In the layer erasure of the present embodiment, the voltage applied to the word line WL (WL3) connected to the gates of selected memory cell transistors (MT3) is not limited to the ground voltage (0 V), the voltages Vm2 applied to the word lines WL (WL2 and WL4) connected to the gates of the adjacent memory cell transistors (MT2 and MT4) are not limited to 10 V, and the voltages Vm3 applied to the word lines WL (WL0 to WL1, and WL5 to WL7) connected to the gates of the non-selected memory cell transistors (MT0 to MT1, and MT5 to MT7) are not limited to 16 V. As long as the same effect as in the layer erasure according to the present embodiment can be obtained, voltages different from the above voltages may be applied to the word line WL3, the word lines WL2 and WL4 and the word lines WL0 to WL1, and WL5 to WL7, respectively.

The selected memory cell transistors (MT3) that are erasure targets, are in states in which high voltages (0 V−Vera) are applied to portions between the channels and the gates. Due to this high voltage, in the selected memory cell transistors, the threshold voltage decreases to the “ER” state, and the data is erased.

Also, the adjacent memory cell transistors (MT2 and MT4) are in the state in which voltages (Vm2−Vera) are applied to portions between the channels and the gates. However, these voltages are set to be sufficiently small such that the states of the threshold voltages in these adjacent memory cell transistors do not change. Therefore, in the adjacent memory cell transistors, the threshold voltages are maintained in the original states, and the data is not erased.

Also, the non-selected memory cell transistors (MT0 to MT1, and MT5 to MT7) are in the state in which voltages (Vm3−Vera) are applied to portions between the channels and the gates. These voltages are sufficiently small such that the threshold voltages in these non-selected memory cell transistors are not changed. Therefore, also in the non-selected memory cell transistors, the threshold voltages are maintained in the original states, and the data is not erased.

In this manner, in the voltage distributions of FIG. 6, only the data of the selected memory cell transistor is erased, and the data in the adjacent memory cell transistors and the non-selected memory cell transistors are not erased.

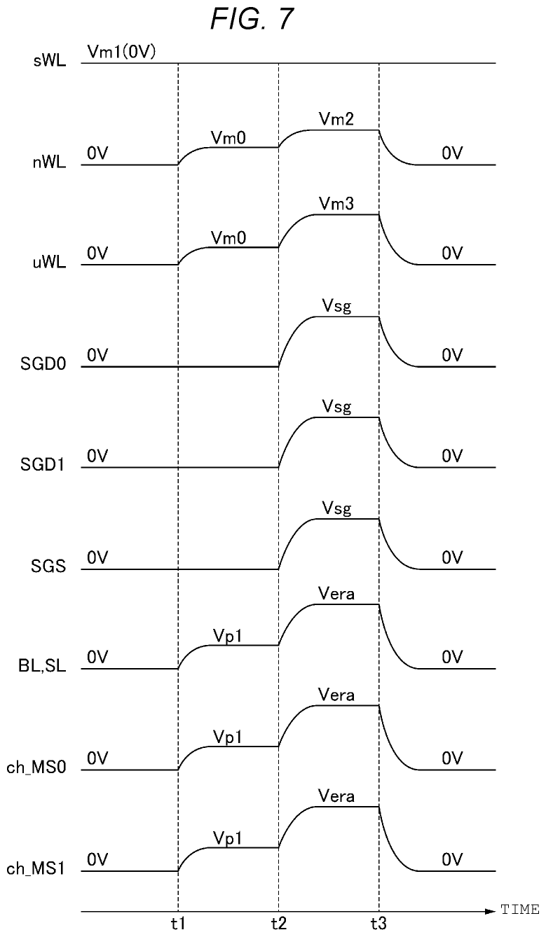

FIG. 7 illustrates an example of a timing diagram for causing voltages of various elements of the memory strings to be in the states as illustrated in FIG. 6. “sWL” of FIG. 7 is an example of a time change of the voltages of the word line WL (in this example, the word line WL3) connected to the selected memory cell transistors. The corresponding word line WL is hereinafter also referred to as a “selected word line sWL”.

“nWL” of FIG. 7 is an example of a time change of voltages of the word lines WL (in this example, the word lines WL2 and WL4) connected to the adjacent memory cell transistors. The corresponding word lines WL are hereinafter also referred to as an “adjacent word line nWL”.

“uWL” of FIG. 7 is an example of the time change of voltages of the word lines WL (in this example, WL0 to WL1, and WL5 to WL7) connected to the non-selected memory cell transistors. The corresponding word lines WL are hereinafter also referred to as a “non-selected word line uWL”.

“SGD0” of FIG. 7 is an example of the time change of the voltage of the select gate line SGD0, and “SGD1” is an example of the time change of the voltage of the select gate line SGD1. “SGS” is an example of the time change of the voltage of the select gate line SGS. “BL, SL” is an example of the time change of the voltages of the bit line BL and the source line SL.

“ch_MS0” of FIG. 7 is an example of the time change of the voltage of the channel of the memory string MS0 (a semiconductor film 330). In the same manner, “ch_MS1” is an example of the time change of the voltage in the channel of the memory string MS1.

In a period before time t1 when the erasing operation starts, the sequencer 41 causes the voltages of the bit lines BL, the word lines WL, and the source line SL to be, for example, 0 V.

At time t1, the sequencer 41 raises all the voltages of the bit lines BL and the source line SL to Vp1. Vp1 is a voltage about Vera−Vsg and is, for example, 7 V. Accordingly, in the select transistors ST1 and ST2, holes are generated, and the channels are charged by the holes. As illustrated in FIG. 7, after time t1, the voltages of ch_MS0 and ch_MS1 rise to Vp1 which is the same voltage of the bit line BL or the like. In this manner, after time t1, the channels of the memory strings MS are pre-charged.

At time t1, the sequencer 41 raises all the voltages of the adjacent word lines nWL and the non-selected word lines uWL to Vm0. “Vm0” is, for example, 3 V. Accordingly, in the memory cell transistors MT other than the selected memory cell transistors, the voltage difference between the pre-charged channels and the gates becomes small. Accordingly, erroneous erasure of data of the memory cell transistors MT is prevented. The voltage of the selected word line sWL remains 0 V after time t1.

At time t2 after time t1, the sequencer 41 raises all the voltages of the bit lines BL and the source line SL to Vera. In addition, the sequencer 41 raises all the voltages of the select gate lines SGD0, SGD1, and SGS to Vsg. The voltages of ch_MS0 and ch_MS1 rise to Vera due to the holes generated in the select transistors ST1 and ST2. The voltages of the channels of the other memory strings that belong to the same block BLK as the memory strings MS0 and MS1 also rise in the same manner.

At time t2, the sequencer 41 raises the voltage of the adjacent word line nWL to Vm2 and raises the voltage of the non-selected word line uWL to Vm3. Accordingly, the voltages illustrated in FIG. 6 is realized, and data of the selected memory cell transistors is selectively erased. If the selective erasure is completed, at time t3, the voltages of the elements, for example, return to 0 V.

During selective data erasure, it is possible to set the voltages of the word lines WL connected to all of the non-selected memory cell transistors to be the same voltage (Vm2) as the voltage of the word line WL connected to the adjacent memory cell transistors.

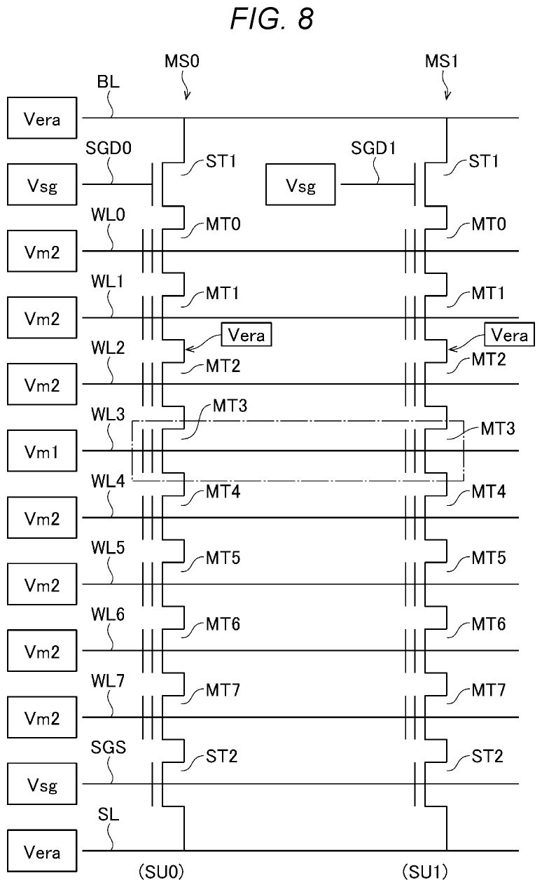

In FIG. 8, an example in which the erasing operation is performed by causing all voltages of the word lines WL connected to the memory cell transistors MT other than the selected memory cell transistors to be Vm2 is illustrated as a comparative example of the present embodiment. Also, in this comparative example, the memory cell transistors MT3 of the memory strings MS are erasure targets, and the other memory cell transistors MT are not erasure targets.

Also in case of setting the voltages as illustrated in FIG. 8, in the same manner as in the selected memory cell transistors of the present embodiment, the memory cell transistors MT3 that are erasure targets are in a state in which high voltages (0 V−Vera) are applied to portions between the channels and the gates. According to the voltages, data is erased from the selected memory cell transistors.

In the same manner as in the adjacent memory cell transistors of the present embodiment, the other memory cell transistors MT are in a state in which voltages (Vm2−Vera) are applied to portions between the channels and the gates. These voltages are sufficiently small such that the states of the threshold voltages in the memory cell transistors MT are not changed, and thus the data of the memory cell transistors MT is not erased. In this manner, also when the voltage distribution as the comparative example of FIG. 8 is set, the same layer erasure as the present embodiment is possible.

Also, in this comparative example, in the memory cell transistors MT other than the erasure targets, the voltages (Vm2−Vera) applied to portions between the channels and the gates are generally voltages of about 10 V in absolute value. As described above, these voltages are sufficiently small such that the states of the threshold voltages of the memory cell transistors MT are not changed. However, if the erasing operation is performed a plurality of times so that such voltages are applied to a portion of the memory cell transistors MT a plurality of times, the threshold voltages may decrease. That is, the threshold voltages in the memory cell transistors MT other than the erasure targets are influenced by the erasing operation, and thus may decrease below the initial values. This phenomenon is referred to as “erasure disturb”.

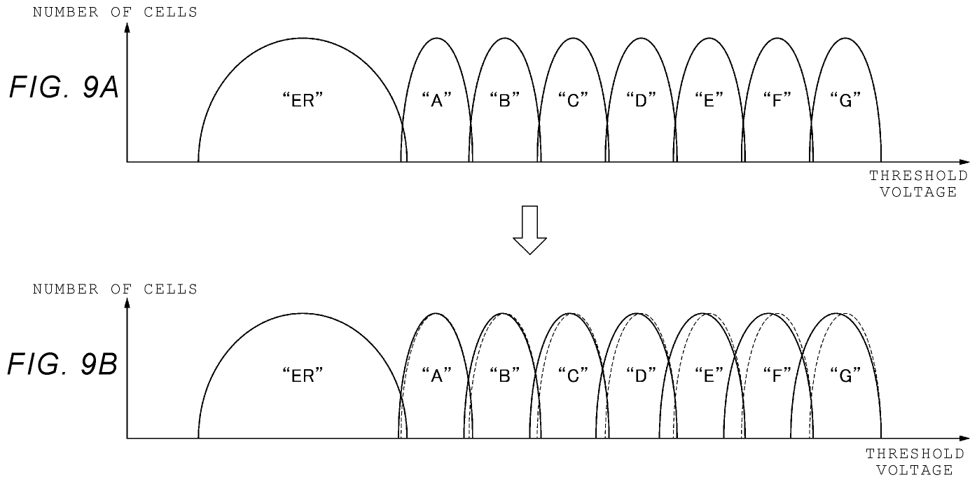

FIG. 9A illustrates the correspondence relationship between the threshold voltages of the memory cell transistors MT (horizontal axis) and the numbers of the memory cell transistors MT (vertical axis).

In FIG. 9A, the threshold voltage distributions adjacent to each other are slightly overlapped with each other. This shows that after a certain period of time has elapsed since the data is written, the distribution ranges of the threshold voltages change. The change in the distribution ranges of the threshold voltages with the elapse of time after the writing of data is referred to as “data retention”. That is, in the middle of FIG. 5, the threshold voltage distributions immediately after the data is written is illustrated, but FIG. 9A illustrates the threshold voltage distributions after a certain period of time has elapsed since the writing of data. As clearly shown by the comparison of both, in the state of FIG. 9A in which the data retention is observed, distribution widths of the threshold voltages in each state are wider than the initial distribution width. Further, even if the threshold voltage distributions change, if the amount of the change is slight, the error correction of the ECC circuit 14 described above can be performed, and thus the read data is not changed.

FIG. 9B illustrates an example of the threshold voltage distributions of the memory cell transistors MT after the voltages of about 10 V are repeatedly applied in the erasing operation. In the same diagram, the upper threshold voltage distribution is illustrated in dotted lines. As illustrated in the same diagram, if the voltages of about 10 V are repeatedly applied, the distribution ranges of the states change to be lower than the initial values. If the threshold voltages change to move from FIG. 9A to FIG. 9B in addition to the data retention, depending on the sizes, it is likely that the error correction of the ECC circuit 14 cannot be performed.

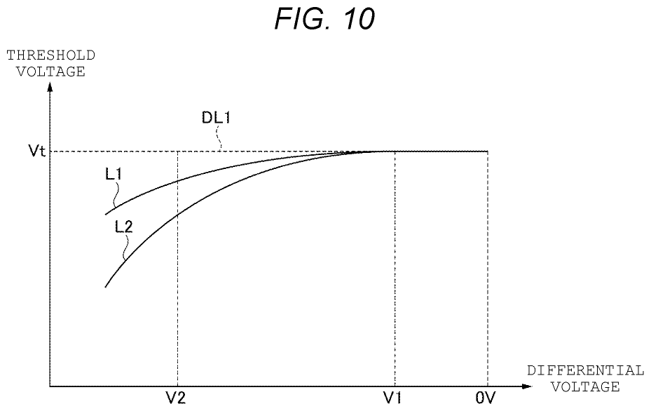

FIG. 10 illustrates the relationships of differential voltages (horizontal axis) and threshold voltages (vertical axis) in the memory cell transistors MT. The “differential voltage” is the voltage applied to a portion between the channel and the gate of the memory cell transistor MT as “Vm2−Vera” described above.

A line L1 of FIG. 10 shows the change of the threshold voltage when the application of the differential voltage is repeated a certain number of times. In addition, a line L2 shows the change of the threshold voltage when the application of the differential voltage is further repeated a certain number of times from the line L1.

As illustrated in FIG. 10, when the differential voltage is about V1 that is comparatively small, even if the application of the differential voltage is repeated, the threshold voltage barely decreases and is maintained at Vt which is the initial value. On the other hand, when the differential voltage is about V2 which is comparatively large, the threshold voltage decreases from Vt. In addition, the decrease amount thereof becomes larger as the application of the differential voltage is repeated.

In this manner, in the memory cell transistors MT other than the erasure targets, if the voltages (Vm2−Vera) are repeatedly applied during the erasing operation, the influence of the erasure disturb as illustrated in FIG. 9 increases, and thus the threshold voltages of the memory cell transistors MT change. In the example of FIG. 8, in a majority of the memory cell transistors MT in which the voltages of the word lines WL are set to Vm2, the erasure disturb occurs.

In order to prevent the erasure disturb, it is considered that the voltages of the gates in the memory cell transistors MT other than the erasure targets, that is, Vm2 in the example of FIG. 8, are set to high values to reduce the voltage differences (that is, the differential voltages) between the channels and the gates. However, if Vm2 is set to a high value, for example, in the example of FIG. 8, the voltage difference between the word line WL3 and the word line WL2 which are adjacent to each other becomes too large. Recently, the distance between the word lines WL has become very small, and thus there is a concern that breakdown voltage failure occurs in some portions. Therefore, it is not preferable to set Vm2 in the example of FIG. 8 to a high value.

As above, if the voltages illustrated in the comparative example of FIG. 8 are set, it is difficult to achieve both of the prevention of the erasure disturb and the prevention of the breakdown voltage failure between the word lines WL.

Accordingly, in the present embodiment, the voltages of the gates in the memory cell transistors MT other than the erasure targets are set to two different voltages, Vm2 and Vm3, and are not uniformly set to Vm2 as in FIG. 8. Specifically, as illustrated in FIG. 6, the voltages of the gates of the adjacent memory cell transistor are set to Vm2, and the voltages of the gates of the non-selected memory cell transistors are set to Vm3.

In the present embodiment, the voltage of the selected word line sWL (WL3) is Vm1, and the voltages of the adjacent word lines nWL (WL2 and WL4) are Vm2. Accordingly, the voltage difference (Vm2−Vm1) between these word lines WL is a low voltage difference so that breakdown voltage failure does not occur.

In addition, the voltages of the adjacent word lines nWL (WL2 and WL4) are Vm2 as above, and the voltages of the non-selected word lines uWL (WL1 and WL5) adjacent thereto are Vm3. Accordingly, the voltage difference (Vm3−Vm2) between these word lines WL is a low voltage difference of about 6 V. Therefore, unlike in the portion between the word line WL3 and the word line WL2 in the comparative example of FIG. 8, the voltages between portions of the word lines WL do not become excessively large.

In FIG. 6, in the non-selected memory cell transistors which are in the majority among the memory cell transistors MT other than the erasure targets, the voltages (Vm3−Vera) applied to the portions between the channels and the gates are generally low voltages of about 4V in an absolute value. The voltage is a low voltage that does not change the threshold voltage even if the voltage is repeatedly applied to the memory cell transistors MT a plurality of times, like the differential voltage V1 illustrated in FIG. 10. Therefore, in the non-selected memory cell transistor, the erasure disturb described above does not occur.

Meanwhile, in the adjacent memory cell transistors, the voltages (Vm2−Vera) applied to portions between the channels and the gates are generally about voltages of about 10 V in an absolute value, and thus the erasure disturb is likely to occur. In the present embodiment, the range in which the erasure disturb occurs is narrowed down because the number of the adjacent memory cell transistors is less than the number of memory cell transistors that are affected by erasure disturb in the comparative example, and in addition the effect of erasure disturb is eliminated by the method described below.

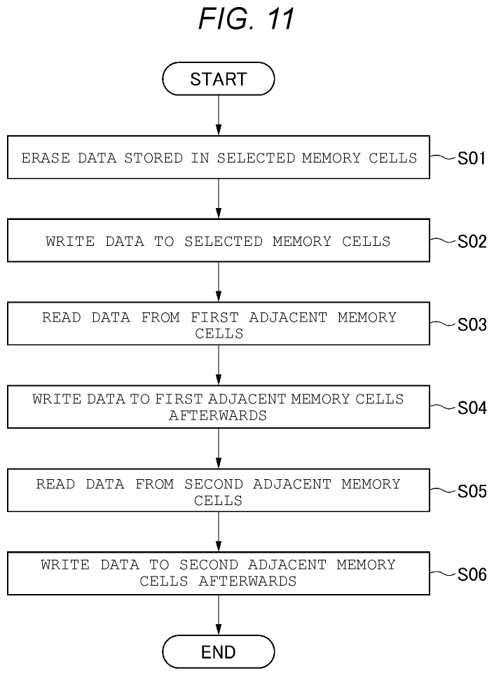

The flowchart illustrated in FIG. 11 indicates a flow of a series of processes performed by the sequencer, which is the control circuit, when the erasing operation is performed.

In S01 which is the first step of the process, a process of erasing data stored in the selected memory cell transistors (in the example of FIG. 6, the memory cell transistors MT3) is performed. A specific method thereof is as described above with reference to FIGS. 6 and 7. When the process of S01 is completed, the threshold voltages of the adjacent memory cell transistors are in a state of being slightly decreased due to the influence of the erasure disturb.

In S02 subsequent to S01, a process of writing new data to the selected memory cell transistors from which data is erased, is performed. Further, when the writing of new data after erasure is not required, the process of S02 may be omitted.

In S03 subsequent to S02, a process of reading data from first adjacent memory cell transistors (in the example of FIG. 6, the memory cell transistors MT2) is performed. Here, all of the memory cell transistors MT connected to the adjacent word lines nWL (in the example of FIG. 6, the word line WL2) are set as targets, and the stored data is read, for example, per page.

Further, the threshold voltages of the adjacent memory cell transistors are slightly decreased due to the influence of the erasure disturb as described above. Therefore, it is likely that, among the adjacent memory cell transistors, there may be memory cell transistors in which the states of the threshold voltages have decreased to states lower than their initial states. However, if the influence of the erasure disturb is small, and the number of such adjacent memory cell transistors is small, the data can be corrected by the error correction of the ECC circuit 14.

In S04 subsequent to S03, “first adjacent memory cell transistors” are subjected to a process of writing back the data that has been read in S03 and error-corrected by the ECC circuit 14. The data is written here, by applying the voltage to the adjacent word lines nWL connected to the first adjacent memory cell transistors without erasing data stored in the first adjacent memory cell transistors. Therefore, in the first adjacent memory cell transistors, the threshold voltages slightly rise. Accordingly, the influence of the erasure disturb on the first adjacent memory cell transistors in S01 can be cancelled.

When the data is written in S04 as above, the program operation and the verification operation may be repeated. Accordingly, the threshold voltages of the first adjacent memory cell transistors can be reliably returned to the initial state. For example, when the initial threshold voltage in the adjacent memory cell transistor is in the “A” state, the program operation and the verification operation may be repeated until it is confirmed that the threshold voltage exceeds the verification voltage VfyA in S04.

In S05 subsequent to S04, a process of reading data from second adjacent memory cell transistors (in the example of FIG. 6, the memory cell transistors MT4) is performed. In the same manner as in S03, all of the memory cell transistors MT connected to the adjacent word lines nWL (in the example of FIG. 6, the word line WL4) are set as targets, and the stored data is read, for example, per page.

In S06 subsequent to S05, “second adjacent memory cell transistors” are subjected to a process of writing back the data that has been read in S05 and error-corrected by the ECC circuit 14. Here, the data is written by the same method as in S04. Therefore, in the second adjacent memory cell transistor, the threshold voltages slightly rise. Accordingly, the influence of the erasure disturb on the second adjacent memory cell transistors in S01 can be cancelled. In S06, the program operation and the verification operation may be repeated in the same manner as in S04.

As described above, the sequencer 41 that is a control circuit in the present embodiment sets the voltage of the word line (WL3) connected to the gates of the selected memory cell transistors (MT3) to Vm1, sets the voltages of the word lines (WL2 and WL4) connected to the gates of the first and second adjacent memory cell transistors (MT2 and MT4) to Vm2 higher than Vm1, and sets the voltages of the word lines (WL0 to WL1, and WL5 to WL7) connected to the gates of the non-selected memory cell transistors (MT0 to MT1, and MT5 to MT7) to Vm3 higher than Vm2. Vm1 corresponds to a “first voltage” in the present embodiment. Vm2 corresponds to a “second voltage” in the present embodiment. Vm3 corresponds to a “third voltage” in the present embodiment. By setting such voltages, only the memory cell transistors MT on a specific layer are set as targets, and the data can be selectively erased.

In the above-described embodiment, the voltages of the gates in the memory cell transistors MT other than the erasure targets are set to different voltages, namely the second voltage and the third voltage, and not set to a uniform voltage. Accordingly, both reduction of erasure disturb and prevention of the breakdown voltage failure between the word lines WL can be achieved.

In the erasing operation, the sequencer 41 performs a process of erasing data stored in the selected memory cell transistors in S01 and then rewriting data to the adjacent memory cell transistors in S04 and S06. The processes performed in S04 and S06 correspond to “post-write processes” in the present embodiment.

In the present embodiment, by performing the post-write process, the influence of the erasure disturb on the adjacent memory cell transistors in S01 can be cancelled. Further, as in the comparative example of FIG. 8, if all the voltages of the gates in the memory cell transistors MT other than the erasure targets are uniformly set to Vm2, it is required to perform a post-write process to all the corresponding memory cell transistors MT. However, in such a case, since the number of the memory cell transistors MT to be the targets is huge, and thus the post-write process requires a long period of time. In contrast, according to the present embodiment, the range in which the erasure disturb occurs is limited only to the adjacent memory cell transistors, and thus the target of the post-write process can be narrowed down, and the time required for the post-write process can be reduced.

A second embodiment is described. Hereinafter, the differences from the first embodiment are mainly described, and the description of points common to the first embodiment are omitted appropriately.

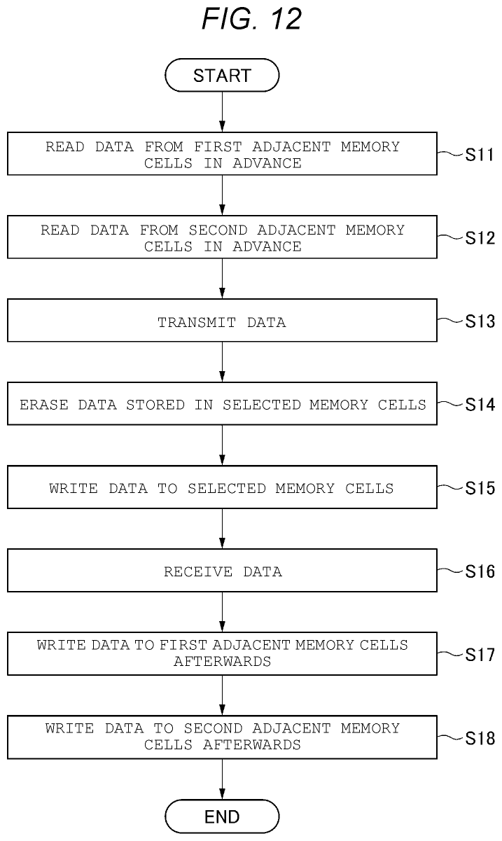

A series of processes illustrated in FIG. 12 is performed instead of the process of FIG. 11, by the sequencer 41 according to the present embodiment.

In S11 that is the first step of the corresponding process, a process of reading data from first adjacent memory cell transistors (in the example of FIG. 6, the memory cell transistors MT2) is performed prior to the erasing of data. Here, all the memory cell transistors MT connected to the adjacent word lines nWL (in the example of FIG. 6, the word line WL2) are set as targets, and the stored data is read, for example, per page.

In S12 subsequent to S11, a process of reading data from second adjacent memory cell transistors (in the example of FIG. 6, the memory cell transistors MT4) is performed. Here, in the same manner as in S11, all the memory cell transistors MT connected to the adjacent word lines nWL (in the example of FIG. 6, the word line WL4) are set as the targets, and the stored data are read, for example, per page.

In S13 subsequent to S12, a process of transmitting and storing data read in S11 and S12 to the external memory controller 1 is performed. The memory controller 1 stores the data transmitted from the semiconductor storage device 2 to the RAM 11. Alternatively, the process of S13 may be performed after the process of S11 is performed, and also after the process of S12 is performed.

In this manner, the sequencer 41 according to the present embodiment performs a process of reading data stored in the adjacent memory cell transistors in S11 and S12 before the data is erased from the selected memory cell transistors. The corresponding processes performed in S11 and S12 correspond to “pre-reading process” according to the present embodiment.

In addition, the sequencer 41 uses the RAM 11 in the external memory controller 1 as a storage device for temporarily storing data obtained in the pre-reading process. Alternatively, when a temporary storage area of data can be allocated in a portion of the memory cell array 110, data obtained by the pre-reading process may be temporarily stored in the area.

In S14 subsequent to S13, in the same manner as in S01 of FIG. 11, a process of erasing data stored in the selected memory cell transistors (in the example of FIG. 6, the memory cell transistors MT3) is performed. In addition, in S15 subsequent to S14, in the same manner as in S02 of FIG. 11, a process of writing new data to the selected memory cell transistors from which data is erased is performed. When the processes of S14 and S15 are completed, the threshold voltages of the adjacent memory cell transistors are in a state of being slightly decreased due to the influence of the erasure disturb.

In S16 subsequent to S15, a process of receiving the data stored in the RAM 11 of the memory controller 1 in S13 from the memory controller 1 is performed. Accordingly, the data obtained by the pre-reading processes of S11 and S12 are obtained.

In S17 subsequent to S16, a process of writing back the data obtained in the pre-reading process of S11 to “first adjacent memory cell transistor” is performed. The writing of data performed herein is performed by applying the voltage to the adjacent word lines nWL connected to the adjacent memory cell transistors, without erasing data stored in the adjacent memory cell transistors. In S17, the program operation and the verification operation are repeated. Accordingly, the threshold voltages of the first adjacent memory cell transistors are restored to threshold voltages of the initial data (that is, the data obtained in the pre-reading process).

In S18 subsequent to S17, a process of writing back data obtained in the pre-reading process of S12 to “second adjacent memory cell transistors” is performed. The writing of data performed herein is performed in the same method as in S17. Accordingly, the threshold voltages of the second adjacent memory cell transistors are restored to the threshold voltages of the initial data (that is, the data obtained in the pre-reading process).

The processes performed in S17 and S18 are the same process as the processes performed in S04 and S06 of FIG. 11, and correspond to the “post-write process” according to the present embodiment. However, in the post-write process of the present embodiment, the data to be written to first adjacent memory cell transistor is data that is read in advance in the pre-reading process of S11 before being influenced by the erasure disturb. In addition, the data to be written to the second adjacent memory cell transistors is data read in advance in the pre-reading process of S12 before being influenced by the erasure disturb.

In this manner, the sequencer 41 of the present embodiment performs a process of rewriting the data read in the pre-reading process to the adjacent memory cell transistors in the post-write process. Accordingly, even when the memory cell transistors MT have characteristics of being greatly influenced by the erasure disturb, according to the method of the present embodiment, the data of the adjacent memory cell transistors may be restored.

Any one method of the method of the first embodiment (FIG. 11) and the method of the present embodiment (FIG. 12) may be employed according to the characteristics of the memory cell transistors MT. For example, when the memory cell transistors MT have characteristics of barely being influenced by the erasure disturb, the method of the first embodiment may be employed. When the memory cell transistors MT have characteristics of being easily influenced by the erasure disturb, the method of the second embodiment may be employed.

It is considered that the post-write process may be performed at the timing before new data is written to the selected memory cell transistors, for example, before S15 in the second embodiment.

However, when new data is written to the selected memory cell transistors, the threshold voltage of the selected memory cell transistors is changed significantly. Therefore, the adjacent memory cell transistors are influenced by the interference between the adjacent cells, and the threshold voltages of the adjacent memory cell transistors are likely to be changed also. That is, the threshold voltages appropriately set by the post-write process are likely to be further changed as a result of the writing of the data to the selected memory cell transistors.

When the post-write process is performed at the timing after the new data is written to the selected memory cell transistors, the threshold voltages of the adjacent memory cell transistors are not influenced by the interference between the adjacent cells as above. Therefore, the threshold voltages of the adjacent memory cell transistors are not changed.

However, the threshold voltages of the selected memory cell transistors are likely to be influenced by the interference between the adjacent cells as a result of the post-write process. However, in the post-write process, the threshold voltages are changed by only a small amount, to return the threshold voltage to the original state, and thus the influence of the interference between the adjacent cells to the selected memory cell transistors becomes negligible.

As described above, the post-write process is preferably performed at the timing after new data is written to the selected memory cell transistors as in the first or second embodiment.

A third embodiment is described. Hereinafter, the differences from the first embodiment are mainly described, and the description of points common to the first embodiment is omitted appropriately.

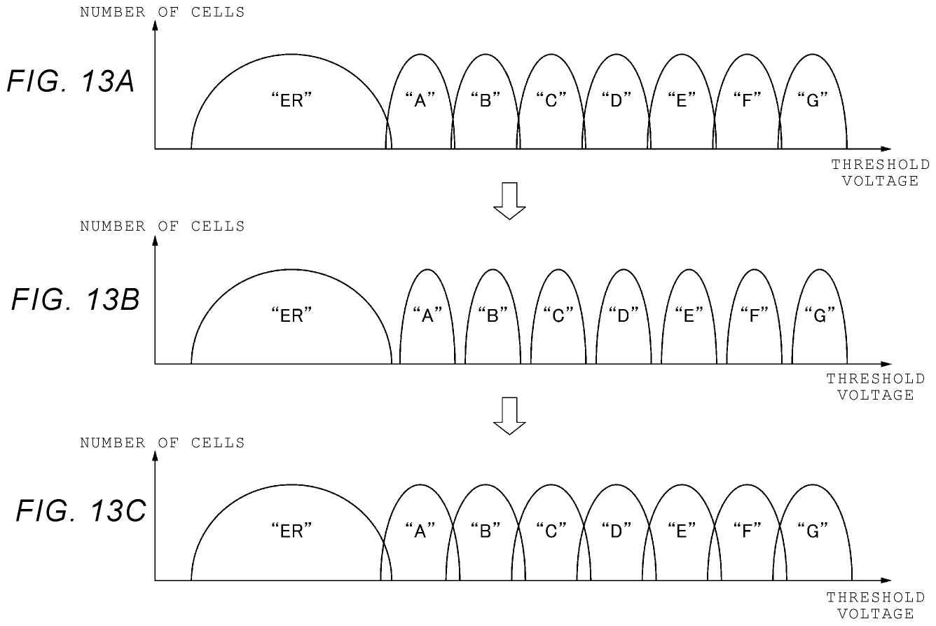

FIG. 13A illustrates a correspondence relationship between the threshold voltages of the memory cell transistors MT (horizontal axis) and the numbers of the memory cell transistors MT (vertical axis) after a certain period of time has elapsed since the data is written. As described with reference to FIG. 9A, when a certain period of time elapses after the data is written, the distribution width of the threshold voltage in each state is in a state of being wider than the initial distribution width due to so-called data retention. Therefore, for example, the distribution width of the “A” state and the distribution width of the “B” state are in a state of overlapping with each other in parts.

In this state, if the selective erasure of the data stored in the selected memory cell transistor is performed, and the threshold voltage of the adjacent memory cell transistor is further changed due to the influence of the erasure disturb, the threshold voltage is likely to exceed the range in which the error correction of the ECC circuit 14 can be performed, depending on the width of the change. As a result, for example, the post-write process in S04 or S06 of FIG. 11 may not be correctly performed.

Therefore, the sequencer 41 according to the present embodiment is configured to perform a process of rewriting data to the adjacent memory cell transistors before the data is erased from the selected memory cell transistors. In this manner, immediately after the data is written, the distribution of the threshold voltage changes from the distribution illustrated in FIG. 13A to the distribution illustrated in FIG. 13B. The distribution of the threshold voltage illustrated in FIG. 13B is the same as the distribution illustrated in the middle of FIG. 5. In the corresponding distribution, for example, all the threshold voltages of the memory cell transistors MT that belong to the “A” state become higher than the verification voltage VfyA. The same applies to the other states.

Thereafter, if the data is selectively erased from the selected memory cell transistors, the threshold voltages of the adjacent memory cell transistors are changed due to the influence of the erasure disturb. As a result, the distribution widths of the threshold voltages in each state become further wider from the states of FIG. 13B to the distribution widths illustrated in FIG. 13C.

However, compared with a case where the data is erased from the selected memory cell transistor in the state of FIG. 13A without change, the distribution widths of each state illustrated in FIG. 13C is reduced. As a result, the change of the threshold voltage can be in the range in which the error correction of the ECC circuit 14 can be performed. Accordingly, for example, the post-write process in S04 or S06 of FIG. 11 can be correctly performed.

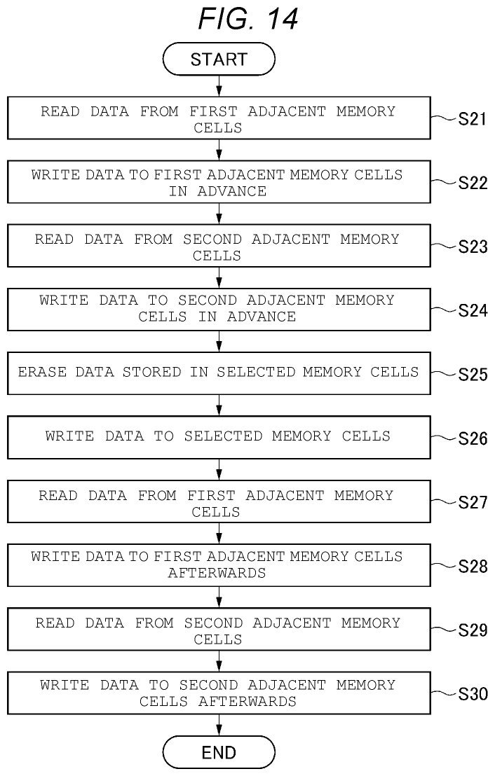

The flow of the processes performed in the present embodiment is described with reference to FIG. 14. A series of processes illustrated in FIG. 14 are performed instead of the processes of FIG. 11 by the sequencer 41 of the present embodiment.

In S21 that is the first step of the processes, a process of reading data from first adjacent memory cell transistors (in the example of FIG. 6, the memory cell transistors MT2) is performed prior to the erasing of data. The process is performed in the same manner as the pre-reading process in S11 of FIG. 12.

In S22 subsequent to S21, a process of writing back data read in S21 to “first adjacent memory cell transistors” is performed. The process is performed in the same manner as the post-write process in S17 of FIG. 12. However, the process of S22 is a process performed before the subsequent data erasure (S14), and thus the process is hereinafter also referred to as a “pre-write process”. By performing the pre-write process, the threshold voltages of the first adjacent memory cell transistors correspond to those of the initial data. Specifically, each threshold voltage has a value higher than the corresponding verification voltage. As a result, the distribution widths of the threshold voltages become smaller, and change, for example, from FIG. 13A to FIG. 13B. In this manner, the pre-write process corresponds to the “process of rewriting data to the adjacent memory cell transistors before the data is erased from the selected memory cell transistors” described above.

In S23 subsequent to S22, a process of reading data from the second adjacent memory cell transistors (in the example of FIG. 6, the memory cell transistors MT4) is performed. The corresponding process is performed in the same manner as the pre-reading process in S12 of FIG. 12.

In S24 subsequent to S23, a process of writing back the data read in S23 to “second adjacent memory cell transistors” is performed. That is, the pre-write process in the same manner as in S22 is performed to the second adjacent memory cell transistors. Accordingly, the pair of adjacent memory cell transistors influenced by the erasure disturb are subjected to the pre-write process, and as a result, the distribution widths of the threshold voltages become small as depicted in FIG. 13B.

Subsequently to S24, the processes performed in S25 to S30 are the same as the processes performed in S01 to S06 of FIG. 11, respectively. In the present embodiment, pre-write processes are performed on the adjacent memory cell transistors in S22 and S24 prior to the erasure of data stored in the selected memory cell transistors in S25, and thus the distribution widths of the threshold voltages become small in advance. Therefore, the post-write processes in the subsequent S28 or S30 can be correctly performed.

A fourth embodiment is described. Hereinafter, the differences from the first embodiment are mainly described, and the description of points common to the first embodiment is omitted appropriately.

In the present embodiment, the erasure of data is not performed for the entire layer connected to the specific word line WL, but performed only for a portion that belongs to the specific string unit SU among the layers connected to the specific word line WL. In other words, the sequencer 41 according to the present embodiment performs an erasing operation so that only a portion corresponding to a specific page becomes selected memory cell transistors among the plurality of memory cell transistors MT connected to the specific word line WL. Therefore, the erasing operation according to the present embodiment can be referred to as “page erasure”. Further, embodiments may be applied to a plurality of word lines WL. Thus, “the specific word line WL” described above may be one word line WL or may be the plurality of word lines WL.

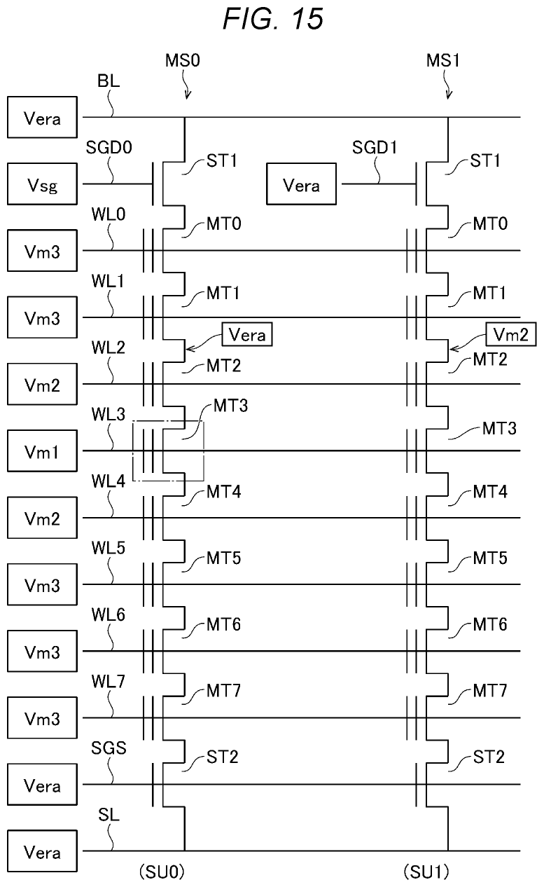

FIG. 15 illustrates the voltages of various elements of the memory strings when the page erasure is performed.

In the example of FIG. 15, among the memory cell transistors MT connected to the word line WL3, a portion that belongs to the string unit SU0 becomes the erasure target. In FIG. 15, the memory cell transistor MT, which is the erasure target, is surrounded by an alternate long and short dash line. Other memory cell transistors MT that are erasure targets are arranged in the depth direction of the paper surface of FIG. 15.

In the example of FIG. 15, among the plurality of memory cell transistors MT that belong to the string unit SU0, the memory cell transistors MT3 of each memory string MS of the string unit SU0 correspond to the “selected memory cell transistors”. In addition, the memory cell transistors MT2 and the memory cell transistors MT4 of each memory string MS of the string unit SU0 correspond to the “adjacent memory cell transistors”, and the memory cell transistors MT0 to MT1, and MT5 to MT7 of each memory string MS of the string unit SU0 correspond to the “non-selected memory cell transistors”.

As illustrated in FIG. 15, even when the page erasure is performed, in the same manner as in the layer erasure of FIG. 6, all voltages of the bit line BL and the source line SL are set to Vera.

In the present embodiment, the voltages of the select gate lines SGS are set to Vera, not to Vsg. As a result, in the select transistors ST2 of each memory string MS, the source line SL and the gates have the same voltages, and thus GIDL is not generated, and the holes from the source line SL do not pass. That is, in the select transistor ST2 of each memory string MS, the movement of the holes causes a state of being cut off.

In the string unit SU0 that include the memory cell transistors MT, which are erasure targets, the voltage of the select gate line SGD0 is set to Vsg in the same manner as in the first embodiment. Meanwhile, in the string unit SU1 which do not include the memory cell transistors MT, which are erasure targets, the voltage of the select gate line SGD1 is set to Vera. In FIG. 15, the same applies to the other string units SU (not illustrated).

In the select transistor ST1 of the memory string MS0, GIDL is generated based on the voltage difference between Vera and Vsg, and the channel of the memory string MS0 is charged with the generated holes. As a result, in the memory string MS0, the voltage of the channel rises to Vera. The same applies to the other memory strings MS in the string unit SU0.

Meanwhile, in the select transistor ST1 of the memory string MS1, the bit lines BL and the gates have the same voltages, and thus GIDL is not generated. That is, in the select transistor ST1 of the memory string MS1, the movement of the holes causes a state of being cut off. In the channel of the memory string MS1, both of the select transistors ST1 and ST2 are in a state of being cut off, and thus the voltage of the channel is not set to Vera. According to the method described below, the voltage of the channel is set to Vm2 lower than Vera. The same applies to the other memory strings MS in the string unit SU1. Further, in FIG. 15, the same applies to the other string units SU (not illustrated).

Also in the present embodiment, the voltage of the word line WL (WL3) connected to the gate of the selected memory cell transistor (MT3) is set to Vm1. In addition, the voltages of the word lines WL (WL2 and WL4) connected to the gates of the adjacent memory cell transistors (MT2 and MT4) are set to Vm2, and the voltages of the word lines WL (WL0 to WL1, and WL5 to WL7) connected to the gates of the non-selected memory cell transistors (MT0 to MT1, and MT5 to MT7) are set to Vm3.

In the memory string MS0 including the memory cell transistors MT, which are erasure targets, the voltage differences between the gates and the channels in each memory cell transistor MT are the same as in the case of the first embodiment (FIG. 6). Therefore, while the data of the selected memory cell transistor (MT3) is erased, the data of the adjacent memory cell transistors (MT2 and MT4) and the non-selected memory cell transistors (MT0 to MT1, and MT5 to MT7) are not erased. The same applies to the other memory strings MS in the string unit SU0.

In the memory string MS1 which does not include the memory cell transistors MT, which are erasure targets, the voltages of the channels are set to Vm2 as described above. The memory cell transistor MT3 of the memory string MS1 is in a state in which the voltages (Vm2−Vera) are applied to portions between channels and gates. Since the voltage is a small voltage so that the state of the threshold voltage is not changed, the data of the memory string MS3 is not erased.

In addition, in the memory cell transistors MT2 and MT4 of the memory strings MS1, the voltages between the channels and the gates are set to 0 V (Vm2−Vm2). Therefore, the data of these memory cell transistors MT2 and MT4 is not erased.

Further, the memory cell transistors MT0 to MT1, and MT5 to MT7 of the memory string MS1 are in a state in which the voltages (Vm3−Vera) are applied to portions between the channels and the gates. Since the voltage is a small voltage so that the state of the threshold voltage is not changed, the data of the memory cell transistors MT0 to MT1, and MT5 to MT7 is not erased.

As above, in the memory string MS1 without the memory cell transistor MT as the erasure target, no data of the memory cell transistor MT is erased. The same applies to the other memory strings MS in the string unit SU1. Further, in FIG. 15, the same applies to the other string units SU (not illustrated).

In this manner, in the voltage distributions illustrated in FIG. 15, the selected memory cell transistors in the string unit SU0 are set as targets, and data for one page is erased. Meanwhile, data of the other memory cell transistors MT is not erased.

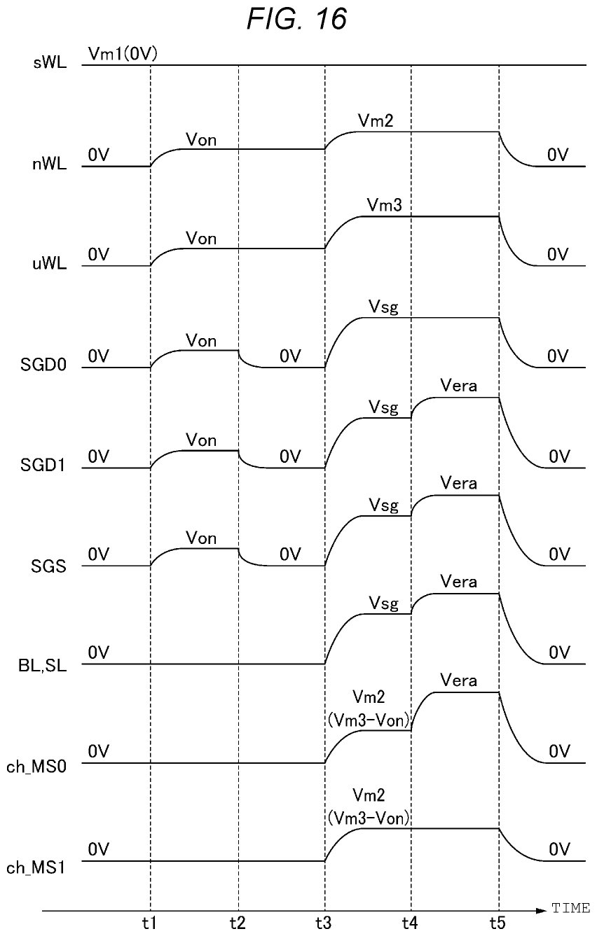

FIG. 16 illustrates an example of the timing diagram for setting the voltages of each unit to be in a state illustrated in FIG. 15 in the same method as in FIG. 7. Hereinafter, in the same manner as in the description of FIG. 7, terms such as “the selected word line sWL”, “the adjacent word line nWL”, “the non-selected word line uWL”, “ch_MS0”, and “ch_MS1” are used.

In the period before time t1 when the erasing operation starts, the sequencer 41 sets the voltages of the bit lines BL, the word lines WL, and the source line SL, for example, to 0 V, respectively.

At time t1, the sequencer 41 raises all the voltages of the adjacent word line nWL, the non-selected word line uWL, and the select gate lines SGD0, SGD1, and SGS to Von. Von is the voltage for transitioning each transistor to an ON state, and for example, 6 V. Von is preferably in the size of Vm3−Vm2 (in this example, 16 V-10 V).

After time t1, all of the select transistors ST1 and ST2 are in the ON states. Therefore, in all the memory strings MS, the voltage of ch_MS0 or ch_MS1 is fixed to the same voltage as the bit line BL or the source line SL, that is, 0 V.

At time t2 after time t1, the sequencer 41 sets all of the voltages of the select gate lines SGD0, SGD1, and SGS, for example, to 0 V. Accordingly, all of the select transistors ST1 and ST2 are in the OFF states, and ch_MS0 and ch_MS1 are in a floating state.

At time t3 after time t2, the sequencer 41 raises all the voltages of the bit lines BL, the source line SL, and the select gate lines SGD0, SGD1, and SGS to Vsg. At this point, in all the memory strings MS, all of the select transistors ST1 and ST2 are still in an OFF state, and ch_MS0 and ch_MS1 are still in a floating state.

The sequencer 41 raises the voltages of the adjacent word lines nWL to Vm2 and raises the voltages of the non-selected word lines uWL to Vm3. At this point, the voltages of the non-selected word lines uWL which are in the majority rise from Von to Vm3. The amount of the change is (Vm3−V0n), that is Vm2. Accordingly, the voltage of ch_MS0 or ch_MS1 rises to Vm2 due to the capacitance coupling.

At this point, in the select transistor ST1, the bit lines BL and the gate have the same voltages, and thus GIDL is not generated. In addition, in the select transistors ST2, the source line SL and the gates have the same voltages, and thus GIDL is not generated. In addition, the holes from the source line SL do not pass.

At time t4 after time t3, the sequencer 41 raises all of the voltages of the select gate lines SGD1 and SGS, the bit lines BL, and the source line SL to Vera.

In the select transistor ST1 of the memory string MS0, GIDL is generated based on the voltage difference between Vera and Vsg, and the channel of the memory string MS0 is charged with the generated holes. As a result, in the memory string MS0, the voltage of ch_MS0 rises to Vera. The same applies to the other memory strings MS in the string unit SU0.

Meanwhile, in the select transistors ST1 of the memory string MS1, the bit lines BL and the gates have the same voltages, and thus GIDL is not generated. Therefore, the voltage of ch_MS1 is still maintained in Vm2. The same applies to the other memory strings MS in the string unit SU1. Further, in FIG. 15, the same applies to the other string units SU (not illustrated).

By the above method, the voltage distribution illustrated in FIG. 15 is realized, and thus the data of the selected memory cell transistor is selectively erased. If the selective erasure is completed, voltages of each unit return, for example, to 0 V at time t5 after time t4.

Also in a case where the page erasure is performed as in the present embodiment, in the adjacent memory cell transistors, the threshold voltages slightly decrease due to the influence of the erasure disturb. Therefore, also in the present embodiment, by the same method as in the first embodiment (FIG. 11), the post-write process to the adjacent memory cell transistors is performed. Accordingly, the threshold voltages of the adjacent memory cell transistors are generally returned to the original values. Before the page erasure, the pre-reading process may be performed by the same method as in the second embodiment (FIG. 12). In addition, before the page erasure, the pre-write process may be performed by the same method as in the third embodiment (FIG. 14).

According to the present embodiment, among the memory cell transistors MT connected to the word line WL3 that is the selected word line sWL, memory cell transistors that do not belong to the string unit SU0 (for example, the memory cell transistors MT3 of the memory string MS1) are set not to be a target of the data erasure. However, according to the present embodiment, the voltage of about (Vm2−Vm1) is applied also to the memory cell transistors MT, and thus in the same manner as in the adjacent memory cell transistors, the threshold voltages thereof are likely to be changed due to the influence of the erasure disturb. Also, after the page erasure is performed as in the present embodiment, among the memory cell transistors MT connected to the selected word lines sWL, the post-write process is preferably performed on the memory cell transistors that are not the erasure target (that do not belong to the string unit SU0), in the same manner as in the adjacent memory cell transistors.

A fifth embodiment is described. Hereinafter, the differences from the first embodiment are mainly described, and the description of points common to the first embodiment is omitted appropriately.

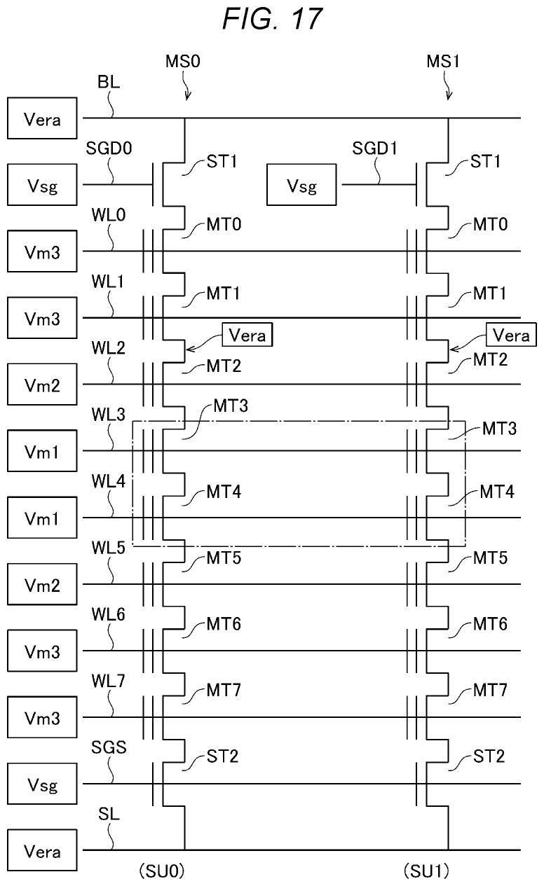

In the erasing operation of the present embodiment, in the same manner as in the first embodiment, data is erased from the entire layers connected to the specific word line WL. However, in the layer erasure according to the present embodiment, the number of the “specific word lines WL” is not one but plural. FIG. 17 illustrates the voltages of various elements of the memory strings during the erasing operation of the present embodiment.

In the example of FIG. 17, all the memory cell transistors MT connected to the word lines WL3 and WL4 are set as erasure targets. In FIG. 17, the memory cell transistors MT, which are erasure targets, are surrounded by an alternate long and short dash line. The memory cell transistors MT, which are erasure targets, include memory cell transistors that belong to the string units SU2 and SU3 (not illustrated) and the other memory cell transistors MT3 and MT4 arranged in the depth direction of the paper surface in FIG. 17.

The word lines WL3 and WL4 correspond to the selected word line sWL in the present embodiment. In this case, the word lines WL2 and WL5 adjacent thereto correspond to the adjacent word lines nWL, and the word lines WL0 to WL1, and WL6 to WL7 correspond to the non-selected word line uWL. Also in the present embodiment, in the same manner as in the above embodiments, during the erasing operation, the voltages of the selected word lines sWL are set to Vm1, the voltages of the adjacent word lines nWL are set to Vm2, and the voltages of the non-selected word lines uWL are set to Vm3.

Further, even when the page erasure as in the fourth embodiment is performed, in the same manner as in the present embodiment, the plurality of word lines WL can be set to the selected word lines sWL.

Also in a case where the plurality of the word lines WL are set to the selected word lines sWL, and data is erased, in the same manner as the above embodiments, in the adjacent memory cell transistors, the threshold voltages slightly decrease due to the influence of the erasure disturb. Therefore, by the same method as in the first embodiment (FIG. 11), the post-write process to the adjacent memory cell transistors may be performed. Accordingly, the threshold voltages of the adjacent memory cell transistors are generally returned to the original values. Before the data erasure, the pre-reading process may be performed by the same method as in the second embodiment (FIG. 12). In addition, before the data erasure, the pre-write process may be performed by the same method as in the third embodiment (FIG. 14).

A sixth embodiment is described. Hereinafter, the differences from the first embodiment are mainly described, and the description of points common to the first embodiment is omitted appropriately.

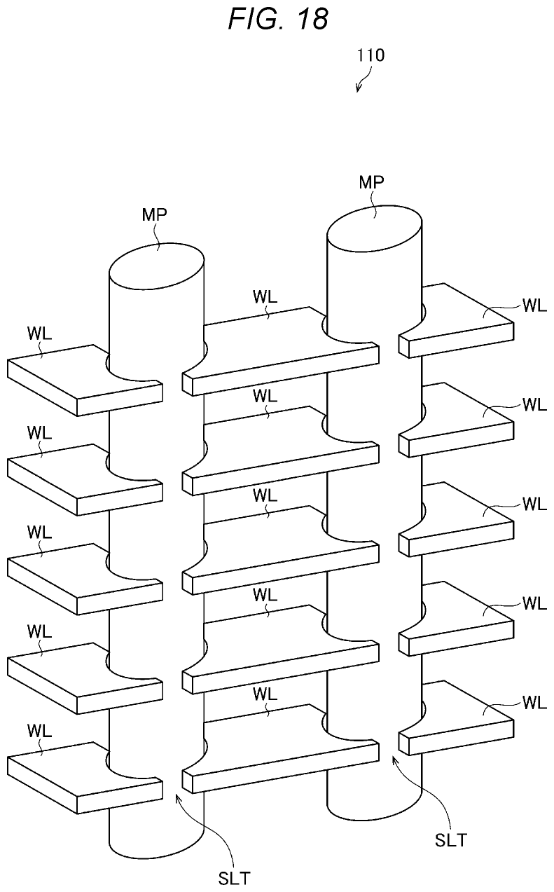

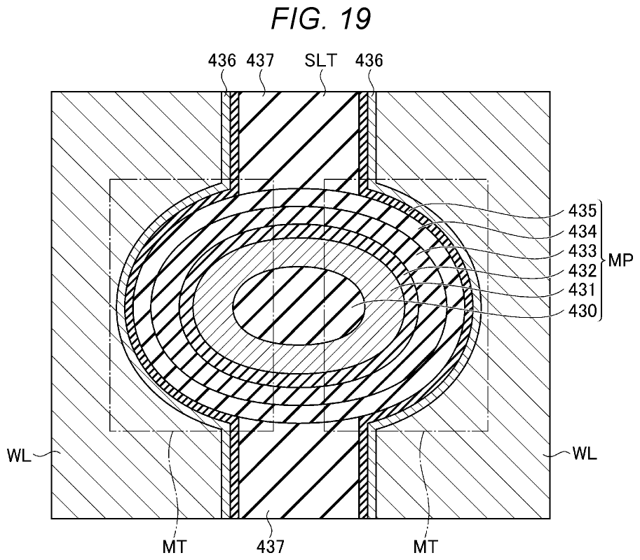

According to the present embodiment, the configuration of the memory cell array 110 is different from the first embodiment. The configuration of the memory cell array 110 in the present embodiment is described with reference to FIGS. 18 and 19. FIG. 18 illustrates two of the memory pillars MP and the word lines WL arranged around the respective memory pillars MP in the memory cell array 110 as a schematic perspective view. Insulating layers are arranged around the memory pillars MP or the word lines WL, but are not illustrated in FIG. 18.

FIG. 19 illustrates a cross-section when the memory pillar MP is cut in the horizontal direction. As illustrated in FIG. 19, the memory pillar MP includes an insulating layer 430, a semiconductor layer 431, and a plurality of insulating layers 432 to 434. The insulating layer 430 is, for example, a silicon oxide film. The semiconductor layer 431 is provided to surround the insulating layer 430 and functions as an area where the channel of the memory cell transistor MT is formed. The semiconductor layer 431 is, for example, a polycrystalline silicon layer. The insulating layer 432 is provided to surround the semiconductor layer 431 and functions as a gate insulating film of the memory cell transistor MT. The insulating layer 432 includes, for example, a stacked structure of a silicon oxide film and a silicon nitride film. The insulating layer 433 is provided to surround the insulating layer 432 and functions as a charge storage layer of the memory cell transistor MT. The insulating layer 433 is, for example, a silicon nitride film. The insulating layer 434 is provided to surround the insulating layer 433 and functions as a block insulating film of the memory cell transistor MT. The insulating layer 434 is, for example, a silicon oxide film.

For example, an AlO layer 435 is provided around the memory pillar MP in this configuration. A barrier metal layer 436 made, for example, of a TiN film is formed around the AlO layer 435. Conductive layers that function as the word lines WL are provided around the barrier metal layer 436.

As illustrated in FIGS. 18 and 19, slits SLT are formed on the word lines WL in the portions intersecting with the memory pillars MP. The word lines WL are divided by the slits SLT. Insulating layers 437 are provided inside the slits SLT.

According to the present embodiment, portions intersecting with the word lines WL on the memory pillars MP function as the memory cell transistors MT. However, according to the present embodiment, the memory cell transistors MT as above are divided by the slits SLT. Therefore, as illustrated in FIG. 19, two of the memory cell transistors MT are formed with the slit SLT interposed therebetween in the portions intersecting with the word lines WL in the memory pillars MP. Accordingly, in the present embodiment, the memory cell transistors MT are arranged at twice the density of the first embodiment.

Even in such a configuration, by performing the same erasing operations in the above embodiments, the same effects as in the embodiments described above can be achieved.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device comprising:
a memory cell array including a plurality of memory cell transistors that are connected to each other in series between a bit line and a source line and a plurality of word lines respectively connected to gates of the memory cell transistors; and
a control circuit configured to control an operation of the memory cell array, including an erasing operation, wherein
in the erasing operation to erase data stored in a selected one of the memory cell transistors, an erase voltage is applied to the bit line and the source line, and while the erase voltage is applied to the bit line and the source line:
a first voltage is applied to the word line connected to the gate of the selected memory cell transistor,
a second voltage higher than the first voltage is applied to the word line connected to the gate of the memory cell transistor adjacent to the selected memory cell transistor, and
a third voltage higher than the second voltage and lower than the erase voltage is applied to the word line connected to the gate of the memory cell transistor not adjacent to the selected memory cell transistor.

2. The semiconductor storage device according to claim 1, wherein the erasing operation further includes a rewrite operation to rewrite data to the adjacent memory cell transistor after erasing the data stored in the selected memory cell transistor.

3. The semiconductor storage device according to claim 2, wherein
the erasing operation further includes a read operation to read data stored in the adjacent memory cell transistor after erasing the data stored in the selected memory cell transistor, and
in the rewrite operation, the data read in the read operation and error-corrected is rewritten to the adjacent memory cell transistor.

4. The semiconductor storage device according to claim 3, wherein the erasing operation further includes a read-write operation before erasing the data stored in the selected memory cell transistor, the read-write operation including reading data stored in the adjacent memory cell transistor and rewriting the data to the adjacent memory cell transistor.

5. The semiconductor storage device according to claim 4, wherein the control circuit performs a write operation to write data to the selected memory cell transistor after erasing the data stored in the selected memory cell transistor and before the rewrite operation.

6. The semiconductor storage device according to claim 2, wherein
the erasing operation further includes a read operation to read data stored in the adjacent memory cell transistor before erasing the data stored in the selected memory cell transistor, and
in the rewrite operation, the data read in the read operation is rewritten to the adjacent memory cell transistor.

7. The semiconductor storage device according to claim 1, wherein in the erasing operation, data is not erased from any of the memory transistors other than the selected memory transistor.

8. A semiconductor storage device comprising:
a memory cell array including a plurality of memory strings, each of which includes memory cell transistors that are connected to each other in series between one of a plurality of bit lines and a source line and a plurality of word lines respectively connected to gates of the memory cell transistors in each memory string; and
a control circuit configured to control an operation of the memory cell array, including an erasing operation, wherein
in the erasing operation to erase data stored in the memory cell transistors connected to a selected one of the word lines, an erase voltage is applied to the bit line and the source line, and while the erase voltage is applied to the bit line and the source line:
a first voltage is applied to the selected word line,
a second voltage higher than the first voltage is applied to the word line adjacent to the selected word line, and
a third voltage higher than the second voltage and lower than the erase voltage is applied to the word line not adjacent to the selected word line.

9. The semiconductor storage device according to claim 8, wherein
each of the memory strings further include a first select transistor connected between the bit line and the memory cell transistors and a second select transistor connected between the source line and the memory cell transistors, and
the first select transistors of a first group of memory strings are commonly controlled and the first select transistors of a second group of memory strings are commonly controlled, but independently controlled with respect to the first select transistors of the first group of memory strings.

10. The semiconductor storage device according to claim 9, wherein
in the erasing operation, data is erased from all memory cell transistors connected to the selected word line.

11. The semiconductor storage device according to claim 9, wherein
in the erasing operation, data is erased from all memory cell transistors of the first group of memory strings that are connected to the selected word line, but not from the memory cell transistors of the second group of memory strings that are connected to the selected word line.

12. The semiconductor storage device according to claim 8, further comprising:
a semiconductor substrate; and
a plurality of memory pillars extending above the semiconductor substrate, wherein
the memory strings are formed on opposite sides of each of the pillars.

13. A method of performing an erasing operation in a semiconductor storage device comprising a memory cell array that includes a plurality of memory cell transistors that are connected to each other in series between a bit line and a source line and a plurality of word lines respectively connected to gates of the memory cell transistors, said method comprising:
applying an erase voltage to the bit line and the source line; and
while the erase voltage is applied to the bit line and the source line, applying a first voltage to the word line connected to the gate of a selected one of the memory cell transistors, applying a second voltage higher than the first voltage to the word line connected to the gate of the memory cell transistor adjacent to the selected memory cell transistor, and applying a third voltage higher than the second voltage and lower than the erase voltage to the word line connected to the gate of the memory cell transistor not adjacent to the selected memory cell transistor.

14. The method according to claim 13, wherein the erasing operation further includes a rewrite operation to rewrite data to the adjacent memory cell transistor after erasing the data stored in the selected memory cell transistor.

15. The method according to claim 14, wherein
the erasing operation further includes a read operation to read data stored in the adjacent memory cell transistor after erasing the data stored in the selected memory cell transistor, and
in the rewrite operation, the data read in the read operation and error-corrected is rewritten to the adjacent memory cell transistor.

16. The method according to claim 15, wherein the erasing operation further includes a read-write operation before erasing the data stored in the selected memory cell transistor, the read-write operation including reading data stored in the adjacent memory cell transistor and rewriting the data to the adjacent memory cell transistor.

17. The method according to claim 16, further comprising:
performing a write operation to write data to the selected memory cell transistor after erasing the data stored in the selected memory cell transistor and before the rewrite operation.

18. The method according to claim 14, wherein
the erasing operation further includes a read operation to read data stored in the adjacent memory cell transistor before erasing the data stored in the selected memory cell transistor, and
in the rewrite operation, the data read in the read operation is rewritten to the adjacent memory cell transistor.

19. The method according to claim 13, wherein
the memory cell array further includes a plurality of memory strings, each including a plurality of memory cell transistors that are connected to each other between one of a plurality of bit lines and the source line, the plurality of word lines being respectively connected to gates of the memory cell transistors in each memory string, and
in the erasing operation, data is erased from all memory cell transistors connected to the word line connected to the gate of the selected memory cell transistor.

20. The method according to claim 13, wherein
the memory cell array further includes a plurality of memory strings, each including a plurality of memory cell transistors that are connected to each other between one of a plurality of bit lines and the source line, the plurality of word lines being respectively connected to gates of the memory cell transistors in each memory string, and
in the erasing operation, data is erased from some of the memory cell transistors connected to the word line connected to the gate of the selected memory cell transistor, and not erased from remaining of the memory cell transistors connected to the word line connected to the gate of the selected memory cell transistor.
